(19) United States
(12) Patent Application Publication
(10) Pub. No.: US 2026/0197984 A1
(43) Pub. Date: Jul. 9, 2026

(54) MICRO-TRANSFER-PRINT REPAIR ON SAME SITE

(71) Applicants: Ronald S. Cok, Rochester, NY (US); Christopher Michael Verreen, Raleigh, NC (US); Erich Radauscher, Raleigh, NC (US); Christopher Andrew Bower, Raleigh, SC (US); Matthew Meitl, Durham, NC (US)

(72) Inventors: Ronald S. Cok, Rochester, NY (US); Christopher Michael Verreen, Raleigh, NC (US); Erich Radauscher, Raleigh, NC (US); Christopher Andrew Bower, Raleigh, SC (US); Matthew Meitl, Durham, NC (US)

(21) Appl. No.: 19/441,215

(22) Filed: Jan. 6, 2026

Related U.S. Application Data
(60) Provisional application No. 63/742,612, filed on Jan. 7, 2025.

(51) Int. Cl. H05K 13/04; G01R 31/26; H05K 1/181; H05K 3/341; H05K 13/00

(52) U.S. Cl. CPC H05K 13/0486; G01R 31/2601; H05K 1/181; H05K 3/341; H05K 13/0015; H05K 13/0473

(57) ABSTRACT

A method of constructing an interconnected system includes providing a target substrate having a device location and first and second spatially separated contact locations in, on, or adjacent to the device location over the target substrate. A first device is disposed onto the target substrate at the device location, connected to the first contact location and tested. If the first device fails the test, it is removed, and a second device is disposed at least partly in and overlapping the device location and is connected to the second contact location. An interconnected system can include the target substrate, first and second contact locations, a second device in the device location connected to the second contact location, and a damaged or disconnected connection portion of the first contact location or connection to the first contact location.

### CROSS-REFERENCE TO RELATED APPLICATION

This patent application claims the benefit of U.S. Provisional Patent Application No. 63/742,612 , filed Jan. 7, 2025, which is incorporated by reference herein in its entirety.

### FIELD OF THE DISCLOSURE

The present disclosure relates to structures and methods for repairing an interconnected system having micro-transfer-printed devices on a target substrate at a device location.

### BACKGROUND OF THE DISCLOSURE

Micro-transfer printing removes a device from a device source wafer and transfers the device to a target substrate using a transfer printer with a visco-elastic stamp. After transfer, micro-transfer-printed devices can be electrically connected using thin-film or other interconnection techniques to construct a desired interconnected system. In some methods, micro-transfer-printed devices can be electrically connected using interconnect-at-print methods using electrical connection posts protruding from a bottom side of the device that contact and electrically connect with contact pads formed on the target substrate. For example, U.S. Pat. No. 10,468,363 by Prevatte et al. entitled Chiplets with Connection Posts and U.S. Pat. No. 8,889,485 by Bower entitled Methods for Surface Attachment of Flipped Active Components disclose the use of connection posts together with micro-transfer printing.

The yield and reliability of a transfer-printed system relies at least in part on the device yield, the device transfer yield, and the electrical connection reliability. If a defective device is constructed on a source wafer and transferred into a system on a target substrate, the system will be faulty. If a device fails to transfer to the target substrate, fails on the target substrate after transfer, or is improperly electrically connected, the interconnected system will also fail. Faulty devices made on a source wafer can be tested before transfer to avoid printing bad devices, for example only known-good-die (KGD) can be transferred. However, such a test process can be difficult or can fail. Moreover, transferring only known-good-die does not address devices that fail to transfer, fail after transfer, or that are improperly electrically connected on a target substrate after transfer.

Given limitations in micro-transfer-printing manufacturing processes, faults can occur and, rather than discarding faulty electronic systems, faulty electronic systems can be repaired in some cases, thereby improving electronic system manufacturing yields and reducing manufacturing costs. U.S. Pat. No. 9,786,646 entitled Matrix Addressed Device Repair by Cok et al. describes displays comprising pixel structures with inorganic LEDs and an additional LED location for each LED. The additional LED can be micro-transfer printed into the additional LED location to replace or supplement a faulty LED. Electrical connections to a faulty LED can be cut to electrically isolate the faulty LED. The additional location requires additional area over the display substrate, reducing system density.

Transfer-printed systems can comprise many (e.g., hundreds or thousands of) unpackaged bare semiconductor die or micro-modules adhered to a target substrate with an adhesive. Since some of the transfer-printed devices can be faulty, can have a faulty electrical connection to the target substrate, or can fail after transfer and electrical connection, there is a need for methods and structures that improve micro-transfer-printed system yields and reliability.

### SUMMARY

Embodiments of the present disclosure provide systems, device, and methods having fewer failures, better yields, and improved reliability.

In accordance with embodiments of the present disclosure, a method of constructing an interconnected system can comprise providing a target substrate having a device location, a first contact location in, on, or adjacent to the device location, and a second contact location in, on, or adjacent to the device location. The first contact location can be spatially separate from the second contact location. Methods can comprise disposing a first device onto the target substrate at the device location, connecting the first device to the first contact location, and testing the first device. If the first device fails the test, the first device is determined to be faulty and methods can comprise removing the first device, disposing a second device at least partly in the device location, and connecting the second device to the second contact location.

The first contact location can be connected to the second contact location with a connection. Some embodiments comprise disconnecting the first contact location from the second contact location, for example by laser cutting the connection after the first device is determined to be faulty.

In some embodiments, the first device and the second device have a same functionality or are substantially identical, for example within the limits of manufacturing variability. In some embodiments, the first device and the second device have substantially a same size. In some embodiments, the first device and the second device have substantially a same aspect ratio. In some embodiments, the first device and the second device have substantially a same size and a same aspect ratio. In some embodiments, the first device and the second device are substantially similar or identical.

In some embodiments, methods can comprise connecting the first device to the first contact location with a thin-film interconnect, with a connection post, with a pattern-printed conductive or transmissive connector or wire, or with wire bonding. In some embodiments, methods can comprise connecting the second device to the second contact location with a thin-film connection, with a pattern-printed conductive or transmissive connector or wire, with a connection post, or with wire bonding. A conductive connector can be electrically conductive. A transmissive connector or connection can be optically transparent and a waveguide. A connector can also be a connection that enables signals to pass to and from the first device through or with the first contact location and enables signals to pass to and from the second device through or with the second contact location. The first contact location can be, comprise, or be disposed in a first target contact pad, for example disposed on or over the target substrate. The second contact location can be, comprise, or be disposed in a second target contact pad, for example disposed on or over the target substrate and spatially separated from the first target contact pad. A contact location can be a portion of a connection or connector, e.g. a portion of a wire or waveguide and need not be structurally distinguished from other portions of the wire or waveguide (but are indicated in the drawings for clarity).

Methods of the present disclosure can comprise micro-transfer printing the first device onto the target substrate at the device location. Methods of the present disclosure can comprise micro-transfer printing the second device onto the target substrate at the device location. At the device location can mean at least partially or completely within the device location, for example a device location as defined by the area of the target substrate occupied by the first device.

In some embodiments, the first device can comprise a connection post and methods of the present disclosure can comprise connecting the first device to the first contact location by pressing the connection post to the first contact location by micro-transfer printing. In some embodiments, the second device comprises a connection post and methods of the present disclosure can comprise connecting the second device to the second contact location by pressing the connection post to the second contact location by micro-transfer printing.

In some embodiments, the target substrate can comprise a first connection post disposed in the first contact location (e.g., can comprise the first target contact pad), the first device can comprise a device contact pad, and methods of the present disclosure can comprise connecting the first device to the first contact location by pressing the device contact pad to the first connection post by micro-transfer printing. In some embodiments, the target substrate can comprise a second connection post disposed in the second contact location (e.g., can comprise the second target contact pad), the second device can comprise a device contact pad, and methods of the present disclosure can comprise connecting the second device to the second contact location by pressing the device contact pad to the second connection post by micro-transfer printing.

Target substrates can comprise multiple first and second contact locations, for example each first or second contact location corresponding to a device contact pad of the device. In some embodiments, the target substrate can comprise a third contact location in, on, or adjacent to the device location. The third contact location can be spatially separate from the first contact location and from the second contact location and can be connected to the first contact location and to the second contact location. In some such embodiments, methods can comprise removing the second device, disposing a third device at least partially in the device location, and connecting the third device to the third contact location. Such embodiments can comprise two repair attempts to an interconnected system. In some embodiments, the target substrate can comprise a fourth contact location in or adjacent to the device location. The fourth contact location can be spatially separate from the first, second, and third contact locations and can be connected to the first, second, and third contact locations. In some such embodiments, methods can comprise removing the third device, disposing a fourth device at least partially in the device location, and connecting the fourth device to the fourth contact location. Such embodiments can comprise three repair attempts to an interconnected system.

In some embodiments of the present disclosure, first and second devices can be disposed in the same location, for example the device location. In some embodiments of the present disclosure, first and second devices can be disposed in different, overlapping locations, for example both at least partially but at least one not completely in the device location, e.g., of the first device. In some embodiments of the present disclosure, first and second devices can be disposed with a same orientation on or over and with respect to the target substrate or the device location. In some embodiments of the present disclosure, first and second devices can be disposed with a different orientation on or over and with respect to the target substrate or the device location. For example, the second device can be disposed horizontally offset with respect to the first device, where horizontal is parallel to a surface of target substrate on which the first or second device is disposed. In some embodiments, the second device can be disposed rotated with respect to the first device about an axis orthogonal to the horizontal, for example by 22.5, 45, 90, or 180 degrees. In some embodiments, the second device can be disposed both horizontally offset and rotated with respect to the first device.

Similarly, the first contact location can be disposed with a same rotation or horizontal offset as the second contact location with respect to the device location or target substrate. In some embodiments, the first contact location can be disposed with a different rotation or horizontal offset from the second contact location with respect to the device location or target substrate. In some embodiments, the device location has a location area with a center, the first contact location is disposed a first distance from a center of the device location, the second contact location is disposed a second distance from a center of the device location, and the first distance is substantially equal to the second distance, the first distance is less than the second distance, or the first distance is greater than the second distance.

According to some embodiments of the present disclosure, methods can comprise disposing an adhesive on the target substrate before disposing the first device. According to some embodiments of the present disclosure, methods can comprise disposing an adhesive on the target substrate before disposing the second device. Adhesive deposition on the target substrate can be patterned or unpatterned.

Some embodiments comprise disposing an adhesive on the target substrate before disposing the first device, removing the first device, and removing at least a portion of the adhesive. Some embodiments comprise disposing an adhesive on the target substrate before disposing the first device, disposing the first device, soft curing the adhesive, and testing the first device. Some embodiments comprise disposing an adhesive on the target substrate before disposing the first device, disposing the first device, hard curing the adhesive, and testing the first device. Some embodiments comprise disposing an adhesive on the target substrate before disposing the second device, disposing the second device, soft curing the adhesive, and testing the second device. Some embodiments comprise disposing an adhesive on the target substrate before disposing the second device, disposing the second device, hard curing the adhesive, and testing the second device.

In some embodiments, a first adhesive is disposed before disposing the first device and a second different adhesive is disposed after disposing the first device and before disposing the second device. In some embodiments, the cure or reflow temperature of the first adhesive is greater than the cure or reflow temperature of the second adhesive. Some embodiments can comprise disposing a first adhesive on the target substrate before disposing the first device and disposing the second device on the target substrate without disposing a second adhesive on the target substrate. Some embodiments can comprise disposing a first adhesive and curing the first adhesive at a first temperature, disposing a second adhesive and curing the second adhesive at a second temperature less than the first temperature. Some embodiments can comprise disposing a first adhesive and disposing the second device onto the target substrate without a second adhesive. Some embodiments can comprise disposing a first adhesive and curing the first adhesive at a first temperature, disposing the second device onto the target substrate without a second adhesive, and annealing the target substrate at an anneal temperature less than the first temperature. In some embodiments, the adhesive is only soft-cured until all of the devices have been tested and then the adhesive hard-cured.

In some embodiments of the present disclosure, the first device can be removed from the target substrate by any one or combination of mechanical scraping (physically pressing a structure such as a post or pin against the first device), mechanical grinding (physically cutting into a top of the first device with a sharp surface), mechanical cutting (physically slicing or cutting at least a portion of the first device), laser ablation (applying electromagnetic energy to vaporize at least some portion of the first device), high-energy particle ablation (applying energetic particles such as ions or electrons, for example in a beam, to vaporize or cut at least some portion of the first device), or vacuum pulling (applying a low-pressure, e.g., air pressure, to a surface of the first device with a vacuum structure to adhere the first device to the vacuum structure with air pressure and then removing the vacuum structure and the first device from the target substrate).

In some embodiments, the first device or the second device is adhered to the target substrate with van der Waals forces. In some embodiments, both the first device and the second device are adhered to the target substrate with van der Waals forces. Adhesion can be only with van der Waals forces, or exclusive of chemical bonding.

According to embodiments of the present disclosure, connecting the first device to the first contact location can comprise forming an electrical connection. According to embodiments of the present disclosure, connecting the first device to the first contact location can comprise forming an optical connection. According to embodiments of the present disclosure, connecting the second device to the second contact location can comprise forming an electrical connection. According to embodiments of the present disclosure, connecting the second device to the second contact location can comprise forming an optical connection.

In embodiments of the present disclosure, an interconnected system can comprise a target substrate having a device location, a first contact location in, on, or adjacent to the device location, and a second contact location in, on, or adjacent to the device location. The first contact location can be spatially separate from the second contact location. A second device can be disposed at least partly (e.g., completely or only partially) in the device location. A second connection can connect the second contact location to the second device. In embodiments, the first contact location can comprise a damaged or disconnected connection portion. A connection to the first contact location can comprise a damaged or disconnected connection portion. The first contact location can be connected to the second contact location. A cut in a connection can be disposed or located between the first contact location and the second contact location of the connection. In embodiments, the connection portion can be a portion of a thin-film connection in or connected to the first contact location. In embodiments, the connection portion can be an indentation, divot, or hole in a contact pad or connection (connector) in or connected to the first contact location. In embodiments, the connection portion can be a portion of a pattern-printed conductive wire in or connected to the first contact location. In embodiments, the connection portion can be a portion of a photolithographically defined wire in or connected to the first contact location. In embodiments, the connection portion can be a portion of a wire bond. In embodiments, the connection portion can be a disconnected connection portion of a connection to or in the first contact location. By disconnected is meant that the connection portion of a connection to or in the first contact location is not connected to any other active or passive element in the interconnected system, e.g., is electrically or optically isolated.

In some embodiments, the device (e.g., the first device, the second device, or both the first and the second devices) is a micro-transfer-printed device that comprises a broken (e.g., fractured) or separated tether. In some embodiments, the device is or is disposed upon a module comprising a module substrate separate, different, and independent from the target substrate. In some embodiments, the device is a bare unpackaged integrated circuit.

In some embodiments, the device comprises a device contact pad having a device contact area, and the device contact area is large enough to connect to a first electrode connected to the first contact location and to a second electrode connected to the second contact location, and the first electrode and the second electrode are disposed at least partly in different locations. In some embodiments, a first electrode and a second electrode connect to a same portion of a device contact area but otherwise are at least partially disposed in or along different portions of the device or target substrate.

In some embodiments, the first device has a first device area, the second device has a second device area, and the first device area is larger than the second device area. In some embodiments, the first device has a first device area, the second device has a second device area, and the first device area is smaller than the second device area. In some embodiments, the first device and the second device have a substantially same device area. In some embodiments, the first device and the second device have a substantially similar shape. In some embodiments, the first device and the second device have a substantially similar form factor. In some embodiments, the first device and the second device are substantially geometrically similar. In some embodiments, the first device and the second device have a substantially same external structure. In some embodiments, the first device has a first center, the second device has a second center, and at least a portion of the second device extends farther from the second center than any portion of the first device extends from the first center. In some embodiments, the first device and the second device are substantially identical (e.g., within manufacturing tolerances and variability).

In embodiments of the present disclosure, the first device, the second device, or both of the first and second devices can have one, two, three, four, five or more device contact pads or connection posts. In some embodiments, the first device, second device, or both the first and second devices can comprise electrically or optically non-functional dummy connection posts. In some embodiments, the target substrate can comprise electrically or optically non-functional dummy connection posts in the device location. In embodiments, the first device, second device, or both the first and second devices comprise functional and off-center connection posts or device contact pads that are not in a line that passes through and are not equidistant from a center of the first or second device, respectively. In embodiments, the target substrate can comprise functional and off-center connection posts or target contact pads in the first contact location(s) that are not in a line that passes through and are not equidistant from a center of the device location. In embodiments, the target substrate can comprise functional and off-center connection posts or target contact pads in the second contact location(s) that are not in a line that passes through a center of the device location. In embodiments, the first contact location and the second contact location can be symmetrically disposed about a center of the device location or a center of the second device. Similarly, in some embodiments the first contact location and the second contact location can be oppositely disposed about a center of the device location or a center of the second device in a line through and equidistant from the center or other point in the device location.

According to some embodiments of the present disclosure, a method of repairing a micro-transfer-printed system can comprise providing a target substrate having a target-substrate surface, a device location, and a first contact location in, on, or adjacent to the device location, disposing a first device onto the target-substrate surface at the device location using micro-transfer printing, connecting the first device to the first contact location, testing the first device, and if the test fails, providing a removal tool and contacting the removal tool to the first device to remove the first device from the target substrate with the removal tool. Embodiments can comprise subsequently disposing a second device on the target-substrate surface at least partly in the device location using micro-transfer printing.

The removal tool can comprise a hardened removal stamp, stamp post, or pin (a removal stamp) and methods can comprise a step of contacting the removal stamp to the first device in any one or any combination of (i) horizontally pressing the removal stamp against a side of the first device that extends at least partly orthogonally to the target-substrate surface (e.g., to knock the first device off of the target substrate); (ii) vertically pressing the removal stamp against a surface of the first device opposite the target-substrate surface and horizontally moving the removal stamp at least partly parallel to the target-substrate surface (e.g., to drag or pull the pressed-against first device across a surface of the target substrate or to cut the first device with a topographic, non-planar structure on an end of the removal stamp in contact with the first device); (iii) vertically pressing the removal stamp against a surface of the first device opposite the target-substrate surface and rotating the removal stamp about an axis at least partly orthogonal to the target-substrate surface (e.g., to grind or cut the pressed-against first device with a topographic, non-planar structure on an end of the removal stamp in contact with the first device); and (iv) heating the hardened removal stamp post or removal pin (e.g., with resistive heating) with a heating element disposed above, on, adjacent to, or within the hardened stamp post. In embodiments, the rotation can be an oscillatory rotation, for example alternating clockwise and counterclockwise directions.

In embodiments, the removal stamp, stamp post, or pin can be at least partly (or completely) stiffer, harder, less compliant, or more rigid than a stamp used for micro-transfer printing a device to a target substrate. In embodiments, the same printing tool can be used to micro-transfer print devices to and remove devices from a target substrate with different stamps, for example a soft and compliant stamp or stamp post for printing devices to a target substrate and a stamp with a harder, stiffer, or more rigid stamp post for removing devices from a target substrate. In some embodiments, a hardened stamp post disposed on or over a rigid support for a removal tool can comprise a stamp structure on a surface (e.g., a distal stamp surface) in contact with a device. The stamp structure can be a non-planar, topographic structure. In some embodiments, the stamp structure can complement (e.g., be an inverse or approximate inverse) a structure on the top of a device so as to increase friction or force applied to the device by the stamp when the stamp structure is in contact with a surface (e.g., a top surface opposite a target substrate) of the device and the stamp is moved relative to the device. The distal stamp surface can comprise a cutting structure, e.g., for rotational cutting or grinding or for linear cutting when the stamp is moved or sheared horizontally against the first device in a direction parallel to a surface of the target substrate on which the device is disposed.

In some embodiments, the removal tool (e.g., comprising a removal stamp) comprises a vacuum apparatus surrounding or adjacent to a removal pin. The vacuum apparatus can comprise at least a portion of a wall only partially surrounding the removal pin defining a gap in the wall and methods of the present disclosure can comprise moving the removal stamp in a direction that is at least partially away from the gap to remove the device so as to contain any particles generated by destroying or otherwise removing the device from the target substrate. Thus, the wall can have or define a gap.

In embodiments, a micro-transfer printing removal tool can comprise a rigid support and a removal pin extending from the rigid support. The removal pin can be a metal protrusion or the removal pin can comprise a polymer such as a relatively hard-cured resin (e.g., PDMS, epoxy, resin, a photoresist, or SU8), optionally coated with a metal, having a cross section with an extent no greater than two hundred, one hundred, fifty, twenty, ten, five, two, or one micron. Devices having such a small extent and thickness can be disposed on a target substrate with micro-transfer printing and removed with such small removal stamps, in particular as compared to conventional mechanical devices.

In embodiments of the present disclosure, an interconnected system can comprise a target substrate having a target-substrate surface, a device disposed on the target-substrate surface, and a patterned electrical or optical conductor disposed on the target-substrate surface continuously extending from the target-substrate surface onto the contact side in electrical or optical contact with the device contact pad. The device can have a thickness orthogonal to the target-substrate surface no greater than one hundred, fifty, twenty, ten, five, two, or one micron and a device contact pad disposed on a contact side of the device opposite the target-substrate surface. In embodiments, the patterned electrical or optical conductor can comprise a cured, sintered, agglomerated, or annealed material disposed using a pattern-printing device. In some embodiments, the patterned electrical or optical conductor can comprise a conductive material distributed in the cured material. In some embodiments, the conductive material can comprise metal nanoparticles, e.g., silver nanoparticles. The patterned electrical or optical conductor can comprise a cured material. The cured material can comprise a resin or epoxy.

In embodiments of the present disclosure, a device can be micro-transfer printed from a device source wafer to a target substrate and can therefore comprise a broken or separated tether.

In embodiments of the present disclosure, an interconnected system can comprise a target substrate having a target-substrate surface, a first device disposed on the target-substrate surface, the first device comprising a first device contact pad on a side of the first device opposite the target-substrate surface, a patterned first connection connecting the first device contact pad to the target substrate with a patterned metal layer, a second device disposed on the target-substrate surface, the second device comprising a second device contact pad on a side of the second device opposite the target-substrate surface, and a patterned second connection connecting the second device contact pad to the target substrate with a cured material comprising annealed, agglomerated or sintered material. The patterned second connection can comprise a conductive material such as nanoparticles distributed in a non-conductive cured material such as a cured polymer. The patterned second connection can comprise polythiophene or a conductive organic or polymer material.

In embodiments of the present disclosure, a method of repairing a micro-transfer-printed system can comprise providing a target substrate having a target-substrate surface and a first contact location, disposing a first device onto the target-substrate surface, the first device comprising a first device contact pad, connecting the first device to the target substrate by evaporating or sputtering a metal layer and patterning the metal layer to form a patterned first connection from the first device contact pad to the target-substrate surface, disposing a second device onto the target-substrate surface, the second device comprising a second device contact pad, and connecting the second device by pattern-wise dispensing a liquid and curing the liquid to form a patterned second connection from the second device contact pad to the target-substrate surface. The patterned second connection can comprise metallic nanoparticles, a conductive polymer, or polythiophene.

Some embodiments of the present disclosure include methods of connecting a micro-transfer-printed micro-device comprising providing a target substrate having a target-substrate surface, a micro-device comprising a device contact pad, a micro-transfer printer, and a pattern-printing device, disposing the micro-device on the target-substrate surface using the micro-transfer printer, disposing a pattern of curable liquid dielectric around at least a portion of a perimeter of the micro-device using the pattern-printing device, and curing the curable liquid dielectric to form a dielectric structure. Disposing the micro-device on the target-substrate surface using the pattern-printing device can include disposing the curable liquid dielectric at least partially on at least a portion of the target-substrate surface. The curable liquid dielectric can be cured to form a cured patterned dielectric structure. Methods of the present disclosure can comprise disposing a pattern of curable liquid conductive liquid in contact with the micro-device and the target substrate over at least a portion of the cured dielectric structure using a pattern-printing device and then curing the liquid conductive liquid, for example to form electrodes or connections.

In some embodiments, an interconnected system can comprise a target substrate having a target-substrate surface, a micro-device disposed on the target-substrate surface, the micro-device comprising a fractured or separated tether, and a cured dielectric material pattern-wise disposed around at least a portion of a perimeter of the micro-device in contact with the micro-device and the target-substrate surface. The micro-device can comprise a device contact pad disposed on a surface of the micro-device opposite the target-substrate surface and comprising a patterned, cured conductive electrode or connection connected to the device contact pad and to the target substrate. The micro-device can have a thickness no greater than fifty, twenty, ten, five, three, two, or one micron.

Some embodiments can include an interconnected system comprising a substrate having a substrate surface, a micro-device disposed on the substrate surface, and a cured dielectric material pattern-wise disposed around at least a portion of a perimeter of the micro-device in contact with the micro-device and the substrate surface.

The present disclosure provides repaired target substrates with micro-transfer-printed devices at device locations on the target substrate, thereby improving manufacturing yields and reducing costs.

### BRIEF DESCRIPTION OF THE DRAWINGS

The foregoing and other objects, aspects, features, and advantages of the present disclosure will become more apparent and better understood by referring to the following description taken in conjunction with the accompanying drawings, in which:

FIG. 1 is a flow diagram illustrating methods according to illustrative embodiments of the present disclosure;

FIG. 2A is a schematic plan view of an interconnected system comprising a first device according to illustrative embodiments of the present disclosure;

FIG. 2B is a schematic cross-section of an interconnected system corresponding to cross-section line A of FIG. 2A according to illustrative embodiments of the present disclosure;

FIG. 2C is a schematic plan view of an interconnected system comprising a second device according to illustrative embodiments of the present disclosure;

FIG. 2D is a schematic cross-section of an interconnected system corresponding to cross-section line A of FIG. 2C according to illustrative embodiments of the present disclosure;

FIGS. 3A-3H are successive cross-sections of structures in an interconnected system corresponding to methods in illustrative embodiments of the present disclosure;

FIG. 4A is an exploded perspective of a first device and target substrate in an interconnected system according to illustrative embodiments of the present disclosure;

FIG. 4B is a perspective of a first device and target substrate in an assembled interconnected system corresponding to FIG. 4A according to illustrative embodiments of the present disclosure;

FIG. 5A is an exploded perspective of a second device and target substrate in an interconnected system according to illustrative embodiments of the present disclosure;

FIG. 5B is a perspective of a second device and target substrate in an assembled interconnected system corresponding to FIG. 5A according to illustrative embodiments of the present disclosure;

FIG. 5C is a perspective of a target substrate having four different contact locations for each connection in an interconnected system according to illustrative embodiments of the present disclosure;

FIG. 6A is a schematic plan view of a first device in an interconnected system and FIG. 6B is a schematic plan view of a second device in an interconnected system according to illustrative embodiments of the present disclosure;

FIG. 7A is a schematic plan view of a first device in an interconnected system and FIG. 7B is a schematic plan view of a second device in an interconnected system according to illustrative embodiments of the present disclosure;

FIG. 8A is a schematic plan view of a first device and first and second contact locations in an interconnected system according to illustrative embodiments of the present disclosure;

FIG. 8B is a schematic plan view of a second device, first contact location, and second contact location rotated with respect to the first device and first contact location in an interconnected system according to illustrative embodiments of the present disclosure;

FIG. 9A is a schematic plan view of a first device and first and second contact locations in an interconnected system according to illustrative embodiments of the present disclosure;

FIG. 9B is a schematic plan view of a second device, first contact location, and second contact location offset with respect to the first device and first contact location in an interconnected system according to illustrative embodiments of the present disclosure;

FIGS. 10A and 10B are schematic plan views of a device comprising a device contact pad large enough to connect with two separate electrodes disposed in two different respective locations according to illustrative embodiments of the present disclosure;

FIGS. 10C and 10D are schematic plan views of a device comprising a device contact pad that can connect with two separate electrodes disposed in two different respective locations according to illustrative embodiments of the present disclosure;

FIGS. 10E and 10F are schematic plan views of a device comprising a device contact pad that can connect with a second electrode disposed at least partly over a first electrode according to illustrative embodiments of the present disclosure;

FIG. 11A is a schematic plan view of a device comprising off-center connection posts and a dummy connection post disposed in a device location according to illustrative embodiments of the present disclosure;

FIG. 11B is a schematic plan view of the device of FIG. 11A disposed in a rotated orientation in the device location according to illustrative embodiments of the present disclosure;

FIG. 11C is a schematic plan view of a device having three off-center device contact pads or connection posts according to illustrative embodiments of the present disclosure;

FIG. 11D is a schematic plan view of a device having four off-center device contact pads or connection posts according to illustrative embodiments of the present disclosure;

FIGS. 12A and 12B are schematic plan views corresponding to FIGS. 11A and 11B including respective connections according to illustrative embodiments of the present disclosure;

FIG. 13A is a schematic cross-section of a device with a thin-film connection in an interconnected system according to illustrative embodiments of the present disclosure;

FIG. 13B is a schematic cross-section of a device with wire bonds in an interconnected system according to illustrative embodiments of the present disclosure;

FIG. 13C is a schematic cross-section of a device with contact pads and a target substrate with connection posts in an interconnected system according to illustrative embodiments of the present disclosure;

FIG. 13D is a schematic cross-section of a device with a thin-film connection disposed on a module substrate in an interconnected system according to illustrative embodiments of the present disclosure;

FIG. 14 is a flow diagram illustrating methods according to illustrative embodiments of the present disclosure;

FIG. 15A is a flow diagram illustrating methods using adhesive layers according to illustrative embodiments of the present disclosure;

FIG. 15B is a flow diagram illustrating methods using annealing according to illustrative embodiments of the present disclosure;

FIG. 16 is a schematic cross section illustrating a hardened stamp dislodging a device using horizontal motion against a side of the device according to illustrative embodiments of the present disclosure;

FIG. 17 is a schematic cross section illustrating a hardened stamp dislodging a device using rotational motion against a top of the device according to illustrative embodiments of the present disclosure;

FIG. 18 is a schematic cross section illustrating a hardened stamp having a structured distal surface dislodging a device having a top surface complementary to the structured distal surface using rotational and horizontal motion against a top of the device according to illustrative embodiments of the present disclosure;

FIG. 19A is a schematic plan view of a removal tool comprising a pin and an enclosing wall with a vacuum port according to illustrative embodiments of the present disclosure;

FIG. 19B is a schematic cross section of the removal tool of FIG. 19A taken across cross section line A according to illustrative embodiments of the present disclosure;

FIG. 20A is a cross section of a device with an uncured pattern-printed dielectric structure according to illustrative embodiments of the present disclosure;

FIG. 20B is a cross section of a device with a cured pattern-printed dielectric structure according to illustrative embodiments of the present disclosure;

FIG. 20C is a plan view of a pattern-printing device depositing dielectric material around a perimeter of a micro-device corresponding to FIG. 20A according to illustrative embodiments of the present disclosure; and

FIG. 21 is a flow diagram of patterning curable connections according to illustrative methods of the present disclosure.

Features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The figures are not drawn to scale since the variation in size of various elements in the Figures is too great to permit depiction to scale.

### DETAILED DESCRIPTION OF CERTAIN EMBODIMENTS

The present disclosure provides a robust structure and method for repairing an interconnected system comprising devices micro-transfer printed from a source wafer to a target substrate in a device location.

According to embodiments of the present disclosure, interconnected systems including a faulty device disposed on the target substrate in a device location can be repaired by removing the faulty device and providing a similar or related replacement (repair) device on the target substrate in the device location in the interconnected system. As used herein, a device site or device location on a target substrate is a spatial location having an area over or on the target substrate in which a device is at least partially or completely disposed. A device is any useful structure, for example having a function in the interconnected system. The device can be a passive or active electronic, optical, or electro-optic device, for example comprising a semiconductor such as silicon or a compound semiconductor. The device can be an integrated circuit, for example made using photolithographic processes. The device can be a bare and unpackaged integrated circuit suitable for micro-transfer printing. The device can be a micro-device, for example having a thickness of no greater than fifty, twenty, ten, five, two, or one micron or a length or width of no greater than two hundred, one hundred, fifty, twenty, ten, five, two, or one micron.

The target substrate can be a passive substrate such as a glass, resin (e.g., a printed circuit board), or polymer substrate or an active substrate, for example comprising a semiconductor such as silicon comprising electronic or opto-electronic circuits. The target substrate can comprise an electronic, optical, or opto-electronic circuit that is functionally connected to the device (e.g., electronically or optically) with connections (e.g., patterned wires or light pipes interconnecting devices disposed on the target substrate). The circuit can be disposed in a thin film coated on the substrate (e.g., to provide thin-film transistor circuits on a dielectric substrate such as glass) or can be constructed in or on an epitaxial layer of the target substrate (e.g., to provide a circuit in a semiconductor substrate). In some embodiments, electronic, optical, or electro-optic devices or components can be disposed and electrically or optically connected on the target substrate to provide a functional, interconnected system for example to devices micro-transfer printed onto the target substrate.

Electrically interconnecting wires (connections) can be formed using photolithography to pattern conductive layers such as metal layers deposited on the target substrate, for example by evaporation, sputtering, or coating. Optical connections can be formed, for example by patterning materials having different optical indices from a bulk portion of the target substrate. In certain embodiments, optical connections are formed by patterning silicon nitride to form optical fibers (optical channels or light pipes) in a silicon dioxide (glass) or silicon target substrate or wafer. In some embodiments of the present disclosure, electrical connections can be made on demand under computer control using a computer program, for example with a pattern-printing device, such as an inkjet, pipette, or capillary printing device, to dispose lines of curable inks (e.g., comprising silver particles that can be sintered to form an electrically conductive wire). In some embodiments of the present disclosure, optical connections can be made on demand under computer control using a computer program, for example using a pattern-printing device to dispose lines of curable, transparent material forming optical waveguides (optical fibers) (e.g., comprising a curable resin or epoxy). Connections can be cut, for example with a laser cutter to locally heat, melt, or ablate material comprising a portion of the connection, thereby preventing the transmission of electrical or optical signals through the connection. An optical connection can be cut by locally changing optical characteristics of a connection thereby preventing or substantially impairing transmission, for example, by using one or more mechanical and/or electrical stimuli.

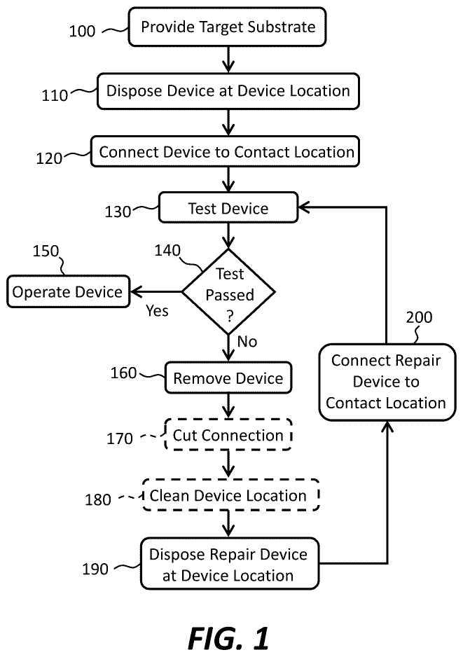

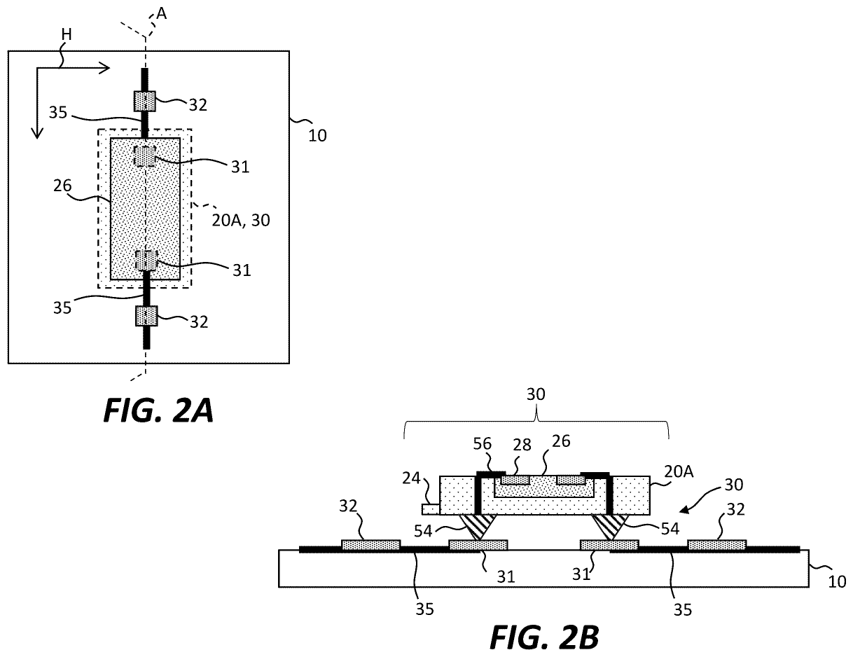

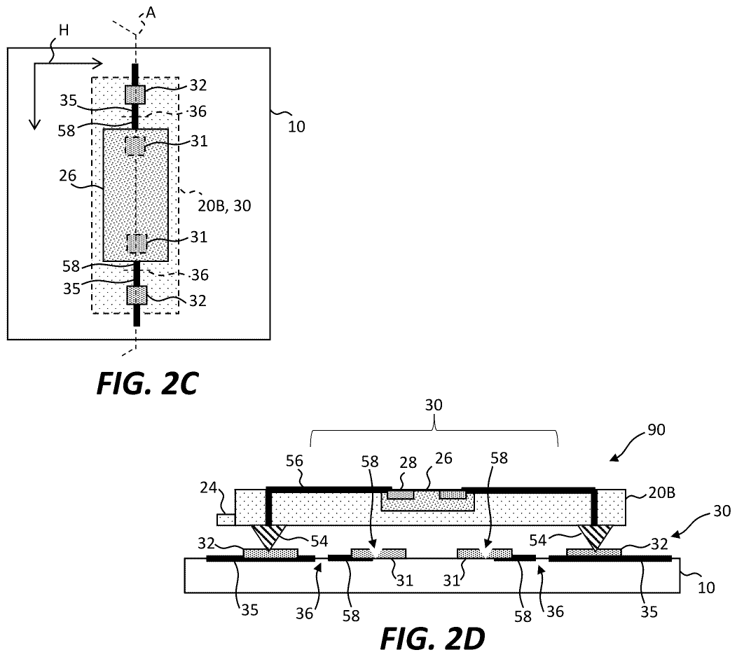

According to embodiments of the present disclosure and as illustrated in the flow diagram of FIG. 1 and the plan and cross section schematics of FIGS. 2A-5B, a method of constructing an interconnected system 90 can comprise providing in step 100 a target substrate 10 having a device location 30, a first contact location 31 in, on, or adjacent to device location 30, and a second contact location 32 in, on, or adjacent to device location 30. Device location 30 can be an area over target substrate 10 in, on, or over which a device 20 is at least partially disposed or located. Device 20 can be in direct contact with or adhered to target substrate 10. First contact location 31 can be spatially separate from second contact location 32 and connected to second contact location 32 with a connection 35, e.g. a connector 35 that can be an electrically conductive wire or an optically transmissive waveguide. Spatially separate can mean disposed or located over a different portion of target substrate 10, e.g., a different spatial portion over or on a surface of target substrate 10 on which device 20 can be disposed. For example, first contact location 31 can be offset from second contact location 32 in a horizontal direction H parallel to a surface of target substrate 10 on which device location 30 is specified and device 20 is disposed. A horizontal direction H on or over target substrate 10 is parallel to a surface of target substrate 10 on which device location 30 is specified and defines a horizontal plane H orthogonal to a thickness direction of devices 20 and orthogonal to a normal of a surface of target substrate 10 on which devices 20 are disposed.

In step 110 and as shown in FIGS. 2A and 2B, a first device 20A can be disposed onto target substrate 10 at least partially in, at, or on device location 30, for example by micro-transfer printing first device 20A from a device source wafer (or device source substrate) to target substrate 10 with a transfer printer, or by using pick-and-place or surface-mount technologies. First device 20A can be electrically or optically connected to first contact location 31 in step 120, for example with a photolithographically defined thin-film connection, conductor, or connector forming an electrode 56 extending to a device contact pad 28 of first device 20A, with a connection post 54 from first device 20A connected to a device contact pad 28 of first device 20A, with a pattern-printed conductive or transmissive wire or waveguide extending to a device contact pad 28 of first device 20A, or with wire bonding to a device contact pad 28 of first device 20A. First contact location 31 can comprise or can be a first target contact pad 31, e.g., an electrical contact pad or optical waveguide or grating disposed on target substrate 10 in first contact location 31. Connection 35 can provide a means to communicate signals, for example electrical signals or optical signals to first contact location 31 and thence to first device 20A. Connection 35 can be an electrically conductive wire or an optically conductive waveguide, optical fiber, or light pipe. A first and second contact location 31, 32 can be provided for each device contact pad 28 of first device 20A. The top view of FIG. 2A and cross-section of FIG. 2B illustrate a structure made with steps 100 through 120 using connection posts 54.

Once first device 20A is connected in step 120, first device 20A can be tested in step 130, for example using probes electrically or optically connected to first target contact pads 31 through connections 35 to provide electrical or optical control signals to first device 20A and detect responses from first device 20A. If first device 20A passes the test in step 140, the system can be put into service and operated in step 150. If first device 20A does not pass the test and is faulty, in step 160 first device 20A can be removed from target substrate 10, for example by mechanical removal (e.g., mechanically scraping first device 20A from target substrate 10, mechanical ablation such as grinding of first device 20A, or mechanical cutting first device 20A), ablation (e.g., exposing first device 20A to a high-power laser beam of radiation or to a high-energy particle beam), or suction (e.g., a low-pressure or vacuum applied to first device 20A with a vacuum collet and the vacuum collet and first device 20A removed from target substrate 10), or a combination of these, or other, methods. Mechanical removal of micro-devices 20 (e.g., faulty first devices 20A) from a target substrate 10 as presently disclosed have been successfully demonstrated. Micro-device 20 removal can, in embodiments of the present disclosure, leave portions of connectors 35 or indentations or holes in connectors 35, first contact location 31, or first target contact pad 31 (a connection portion 58).

In optional step 170 and as shown in FIGS. 2C and 2D, connectors 35 can be cut (e.g., with a cut 36) to prevent any communication between first contact location 31 and second contact location 32, for example using a laser cutter or other means, leaving remnant connection portion 58. By preventing communication between first contact location 31 and second contact location 32, any signals applied to second contact location 32 are not disturbed by any residual or remnant connection portion 58 to first contact location 31, improving interconnected system 90 performance. Remnant connection portion 58 can also comprise damage such as indentations or holes in connectors 35, first contact location 31, or first target contact pad 31, as shown in FIG. 2D.

Device location 30 can optionally be cleaned in step 180, e.g., by blowing clean gas (such as air) over device location 30, rinsing device location 30 with a liquid (such as deionized water), or exposing device location 30 to energetic particles (such as a plasma, for example an oxygen plasma) for example as a field etch operation to remove organic materials such as exposed adhesive 12, or any combination of these. Optional steps 170 and 180 can be done in any desired order or can be repeated.

In step 190, a second device 20B (e.g., a repair device 20B) can be disposed at least partially in device location 30 (e.g., a location of first device 20A), for example by micro-transfer printing second device 20B from a device source wafer (or device source substrate) to target substrate 10 with a transfer printer, or by using pick-and-place or surface-mount technologies, for example as shown in FIGS. 2C and 2D. (First device 20A and second device 20B may be referred to collectively as devices 20 or a device 20.) Second device 20B can be electrically or optically connected to second contact location 32 in step 200, for example with a thin-film connection 35 forming an electrode 56, with a connection post 54, with a pattern-printed conductive or transmissive wire or waveguide, or with wire bonding (e.g., using methods and structures similar to those for connecting first device 20A to first target contact pad 31). Second contact location 32 can comprise or can be a second target contact pad 32, e.g., an electrical contact pad or optical waveguide or grating. Second target contact pad 32 can be a contact pad disposed on target substrate 10 in second contact location 32. Device location 30 can encompass an area over target substrate 10 in which at least a portion or all of first device 20A is disposed and in which at least a portion of or all of second device 20B is disposed. Thus, at least a portion (e.g., all) of first device 20A and at least a portion (e.g., all) of second device 20B is disposed in device location 30 on or over target substrate 10 so that at least a portion or all of first and second devices 20A, 20B are disposed in a same device location 30 on or over target substrate 10. Repair second device 20B can, but does not necessarily, extend spatially beyond faulty first device 20A on target substrate 10 to second target contact pad 32.

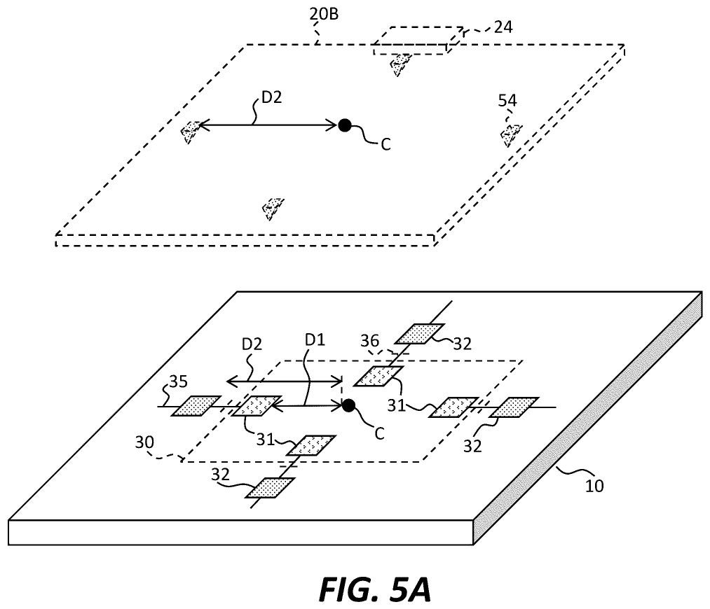

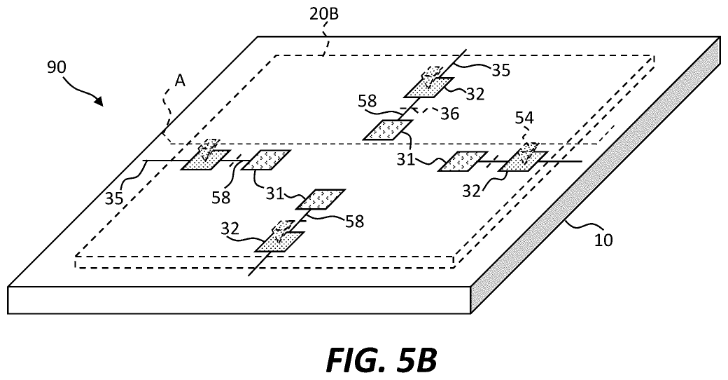

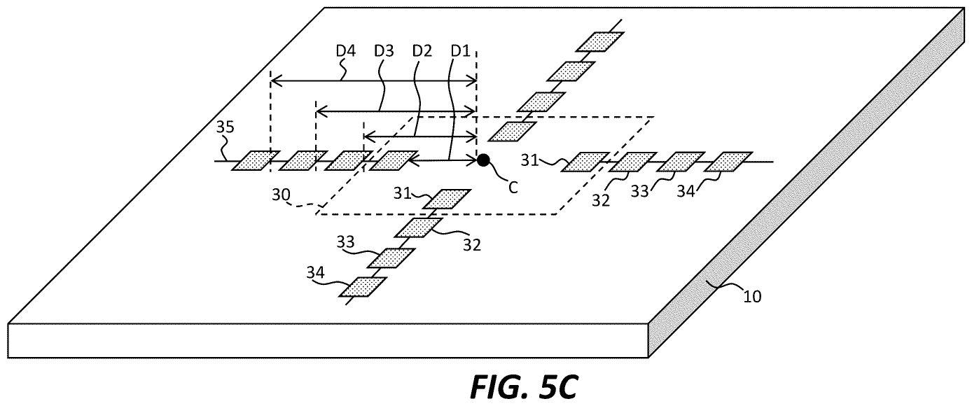

Once connected, repair second device 20B can be tested similarly to the test for first device 20A in step 130. If repair second device 20B passes the test (step 140), it can be put into service and operated (step 150). If not, the repair process can be repeated with any other contact locations (e.g., a third or fourth contact location as shown in FIG. 5C). If no more locations are available, interconnected system 90 fails and can be discarded. Although only first and second contact locations 31, 32 are illustrated in FIGS. 2A and 2B, embodiments of the present disclosure can include any positive integer number of contact locations greater than one, e.g., an initial first contact location 31 for first device 20A and an additional contact location for each repair cycle with repair devices 20 (four sets of contact locations are shown in FIG. 5C).

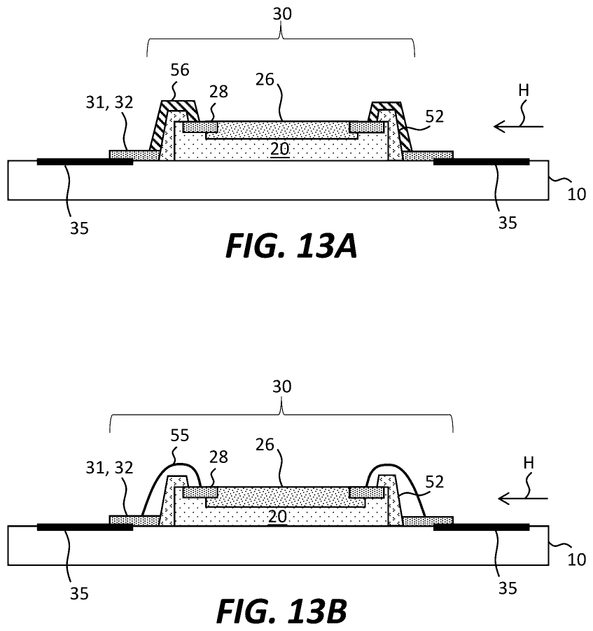

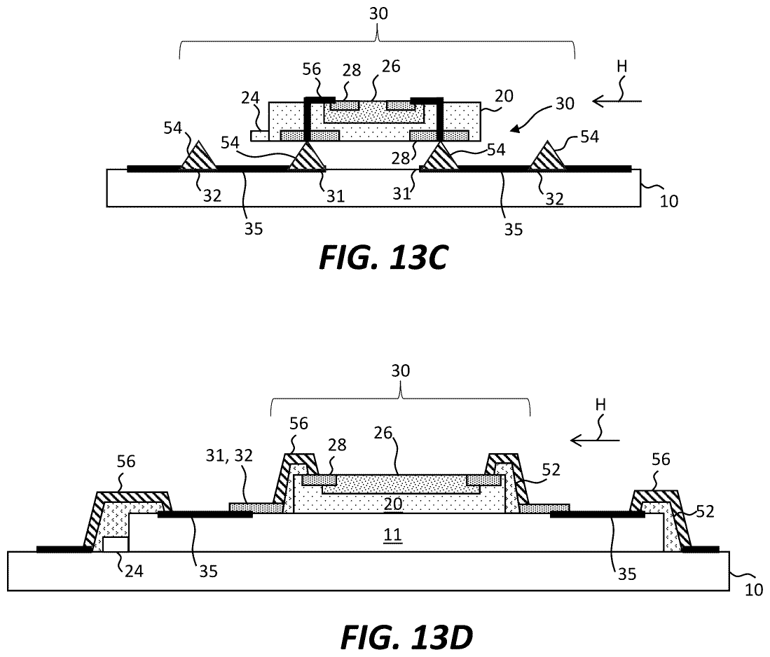

As shown in FIG. 2D, removing first device 20A in step 160 can result in a remnant connection portion 58, for example a damaged portion of connection 35, a portion of a thin-film connection 35, an indentation, divot, or hole in connection 35 or first contact location 31, a portion of a pattern-printed conductive wire in or connected to first contact location 31, or a portion of a wire bond in first contact location 31. Connection portion 58 can be a conductor that is not connected to any other element than first contact location 31, for example because of cut 36. To avoid any interference from remnant connection portion 58, connection 35 can be rendered non-functional between first and second target contact pads 31, 32 with a cut 36, for example using a laser cutter to ablate material of connection 35. Thus, connection portion 58 can be a partial connection (e.g., a portion of connection 35) that is not connected to any other element, for example because of cut 36. Connection portion 58 can also be a portion of connection 35 that extends over target substrate 10 to no element from first contact location 31 (e.g., is disconnected), for example from a location (e.g., first contact location 31 or first target contact pad 31) where first device 20A was located but is no longer present, e.g., because it was removed or destroyed. Connection portion 58 can also be a damaged portion of first contact location 31 or first target contact pad 31, e.g., a divot, hole, or indentation, or a portion of a bond wire 55 (as shown in FIG. 13B using wire bonding methods and materials).

In some embodiments, second device 20B has the same functionality as first device 20A. In some embodiments, second device 20B has a same size as first device 20A. In some embodiments, second device 20B has a different size from first device 20A, for example second device 20B can be larger than first device 20A or second device 20B can be smaller than first device 20A. In some embodiments, first device 20A and second device 20B have a same aspect ratio. In some embodiments, first device 20A and second device 20B are geometrically similar. As used herein, same can mean substantially the same for example as designed and within manufacturing tolerances. Second contact location 32 can be electrically or optically connected to first contact location 31 so that repair second device 20B has the equivalent electrical or optical functionality as a functional first device 20A and operates equivalently as functional first device 20A would in interconnected system 90 if not removed from interconnected system 90. As noted, in some embodiments, if second contact location 32 is electrically or optically connected to first contact location 31 with connection 35, a portion of connection 35 to first contact location 31 can be disconnected or otherwise rendered inoperable with cut 36.

FIG. 2A is a top view of a target substrate 10 having a substantially planar horizontal surface H parallel to the surface on which a device location 30 is disposed. First device 20A can be disposed on or in device location 30 and connected with a connection post 54 to first contact locations 31, for example by micro-transfer printing. First device 20A can comprise a circuit 26 providing functionality to first device 20A (or any device 20). Each second contact location 32 can be connected by a connection 35 to a first contact location 31 (if not cut with cut 36).

FIG. 2B is a cross-section corresponding to FIG. 2A across cross-section line A and illustrates connection posts 54 connected to circuit 26 of first device 20A on target substrate 10 through device contact pads 28 and electrodes 56. Each connection post 54 is connected to a first contact location 31 (e.g., a first target contact pad 31) by micro-transfer printing first device 20A (with connection posts 54) from a device source wafer to target substrate 10. First contact location 31 (e.g., first target contact pad 31) can be connected with connection 35 to second contact location 32 (e.g., second target contact pad 32). This structure corresponds to the result of step 120. Each connection 35 and first contact location 31 can provide a connection 35 to other devices 20 or structures in interconnected system 90. Each second contact location 32 can provide a connection 35 to other devices 20 or structures in interconnected system 90 (not shown), used if first device 20A fails in step 130, together with connection 35.

If first (faulty) device 20A fails in step 130, a second (repair) device 20B can be disposed on device location 30 after removing first device 20A for example by micro-transfer printing, as shown in the plan view of FIG. 2C and cross-section FIG. 2D taken across cross-section line A of FIG. 2C. Removal of first device 20A can result in a connection portion 58 (e.g., a broken remnant connection portion 58). In some embodiments, connection portion 58 can be a hole, indentation, dent, divot, or cavity in first target contact pad 31, for example by micro-transfer printing a device 20 having connection posts 54 (as shown in FIG. 2D). In some embodiments, connection portion 58 can be a portion of an electrical or transmissive conductor disposed in contact with or adjacent to first target contact pad 31, for example solder, a portion of a wire formed by curing an inkjet conductor, a portion of a wire or waveguide formed by photolithography on target substrate 10, or a disconnected connection portion 58 of connection 35 or first contact location 31 that is not connected to any other device, element, or component in interconnected system 90. Connection portion 58 can inhibit the connection of second device 20B to the same first contact location 31, e.g., because of damage to connection 35 or first contact location 31. Thus, according to embodiments, second device 20B can be connected to second contact location 32 rather than first contact location 31. If connection portion 58 does not inhibit the connection of second device 20B to the same first contact location 31 (or no connection portion 58 is present as a consequence of removing first device 20A), second device 20B can be disposed and connected on target substrate 10 by repeating steps 110 and 120. FIGS. 2C and 2D are similar to FIGS. 2A and 2B except for the presence of connection portions 58 and second (repair) device 20B connected to second contact locations 32.

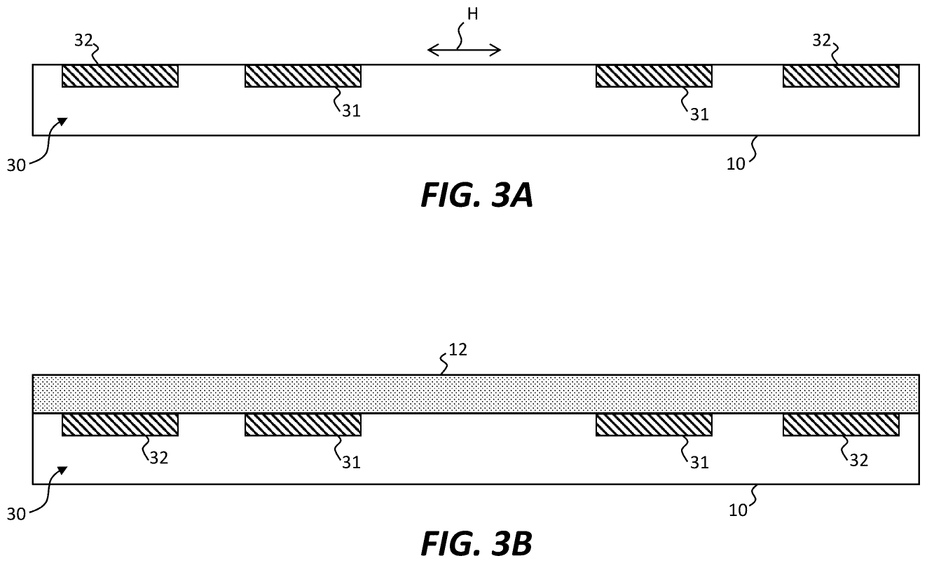

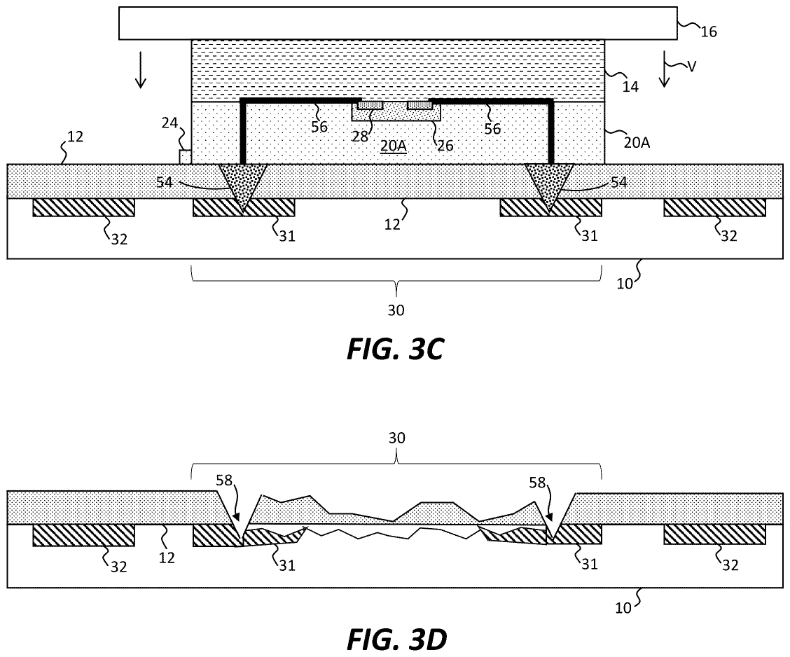

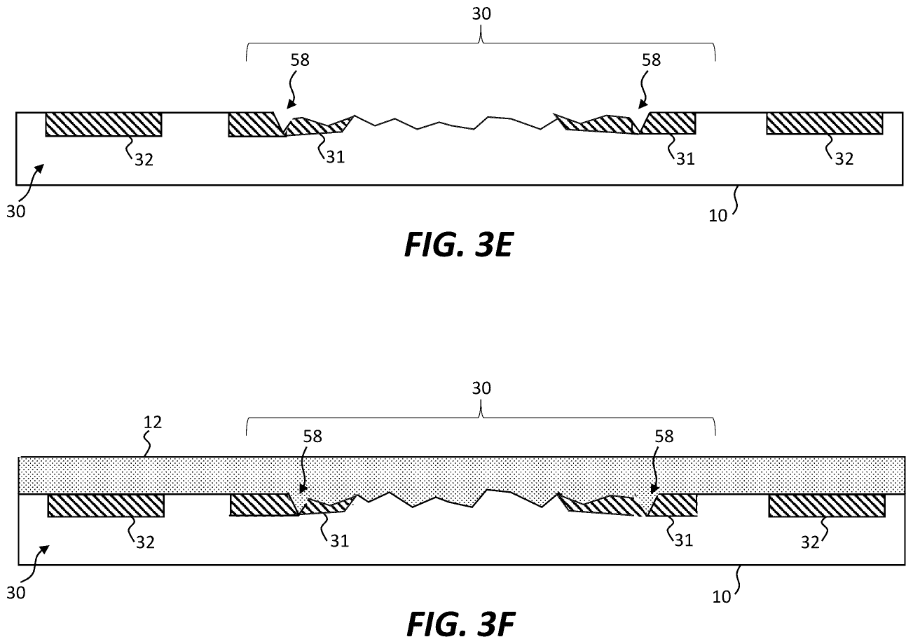

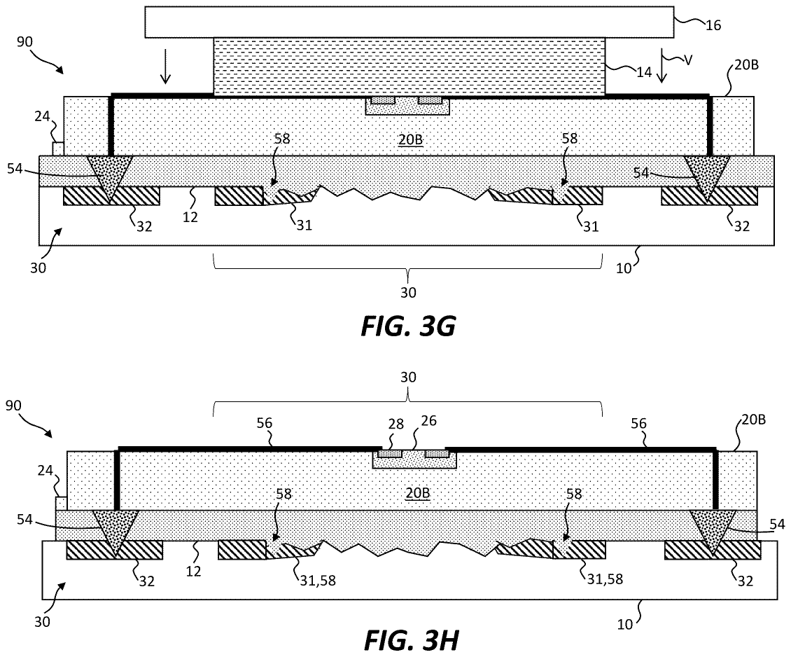

FIGS. 3A-3H are successive cross-sections illustrating structures useful in constructing interconnected systems 90 using methods according to embodiments of the present disclosure. FIG. 3A shows a target substrate 10 having first contact locations 31 (e.g., first target contact pads 31) and second contact locations 32 (e.g., second target contact pads 32) disposed in different spatial locations on target substrate 10 than first contact locations 31. First and second target contact pads 31, 32 can each be an electrically conductive or optically transmissive structure, for example comprising a metal pad or wire or comprising an optical structure such as a waveguide comprising silicon nitride or other optically transmissive material having an optical index different from that of target substrate 10. First and second target contact pads 31, 32 can be photolithographically formed, for example by coating, sputtering, or evaporating material to deposit the material over a surface of target substrate 10 and then patterning the deposited material using photolithography, for example patterned photoresists and etching. In other embodiments, direct writing can be used to form electrically conductive or optically transmissive structures. First and second target contact pads 31, 32 can be locally spatially identical, or different and can have a same size or comprise a same material or can have different sizes or comprise different materials. First and second target contact pads 31, 32 can have no separate function than as a connection to other devices 20 or structures in interconnected system 90 and can be a portion of connection 35. Target substrate 10 can be any useful substrate, for example substrates used in the semiconductor, photonic, or display industries, including glass, polymer, or semiconductor materials. Target substrate 10 can have two opposing substantially parallel and planar sides (e.g., within manufacturing constraints) on one of which first and second target contact pads 31, 32 and first and second devices 20A, 20B are disposed.

FIG. 3B illustrates an optional adhesive layer 12 disposed over target substrate 10 and over first and second contact locations 31, 32. Adhesive layer 12 can be patterned after coating using photolithography or deposited in a pattern, for example using patterned deposition methods and materials, for example comprising a curable liquid material. A first device 20A is disposed over adhesive layer 12, target substrate 10, and first and second contact locations 31, 32, for example by micro-transfer printing with a transfer printer 16 that presses a stamp 14 (e.g., having a stamp post 14 with an adhered first device 20A) that fractures or separates a tether 24 of first device 20A, as shown in FIG. 3C. First device 20A can comprise connection posts 54 electrically connected to circuit 26 in first device 20A through electrodes 56 and device contact pads 28 connected to circuit 26. In some embodiments, connection posts 54 can be formed or disposed on first and second target contact pads 31, 32 on target substrate 10. First device 20A can be pressed against adhesive layer 12 and target substrate 10 to press connection posts 54 through adhesive layer 12 into first target contact pads 31 to form an electrical or optical connection 35 between connection posts 54 and first target contact pads 31, thus performing steps 110 and 120 of FIG. 1 in a common step. In some embodiments, connection posts 54 and first target contact pads 31 can comprise a metal to conduct electrical signals, as shown in FIG. 3C. In some embodiments, connection posts 54 and first target contact pads 31 can comprise an optically transmissive waveguide to transmit optical signals, e.g., with a diffractive grating provided in a waveguide in target substrate 10 to direct light through or into an optical via in first device 20A or directly onto a photosensor (not shown in the Figures). First device 20A can comprise a photosensor to detect optical signals and transmit the detected signal to circuit 26, e.g., as an electrical signal.

In some embodiments, adhesive layer 12 is not used and/or not needed and first device 20A is directly disposed on, e.g., directly printed on, target substrate 10 and can rely on local forces such as van der Waals forces or a physical connection between connection posts 54 and first target contact pads 31 to hold first device 20A in place. Adhesive layer 12 can be an organic material such as a polymer, resin, epoxy, photoresist or other adhesive material. Adhesive layer 12 can be curable, for example, can comprise cross-linking materials when exposed to heat or radiation, such as ultra-violet radiation. If present, adhesive layer 12 can be uncured, soft-cured, or hard-cured. Curing adhesive 12 can more strongly adhere first device 20A to target substrate 10.

Once first device 20A is disposed in place on target substrate 10 and connected to first target contact pad 31 as shown in FIG. 3C, first device 20A can be tested, as in step 130 of FIG. 1, for example by providing electrical probes to electrical conductors on target substrate 10 or optical emitters or sensors applied to connections 35. If the test is passed, first device 20A and target substrate 10 can be put into service in step 150. If not, according to embodiments of the present disclosure, first device 20A is removed, for example using mechanical scraping, grinding, cutting, radiative or particle ablation, or vacuum methods, as shown in FIG. 3D in step 160, leaving connection portions 58 (e.g., remnant transmissive or electrically conductive materials or holes or indentations in first target contact pads 31 from connection posts 54 pressed into first target contact pads 31 in steps 110 and 120).

Optionally, connection 35 can be cut to isolate first target contact pads 31 from second target contact pads 32 (connections 35 or cuts 36 are not shown in FIGS. 3A-3H for clarity).

Target substrate 10 and device location 30 can be cleaned in optional step 180, e.g., with a plasma, rinsing, blowing, or with other chemical cleaners and, in the case of an adhesive layer 12, can remove any exposed adhesive layer 12 (e.g., an organic adhesive such as a resin or epoxy, for example a cured or curable organic material comprising cross-linking polymer materials). This cleaning step can prepare device location 30 receive a second device 20B, as shown in FIG. 3E. As shown in FIG. 3F, an optional adhesive layer 12 can be coated again over target substrate 10 and first and second target contact pads 31, 32. Optional adhesive layer 12 can be patterned using photolithographic methods and materials or disposed in a pattern, e.g., using inkjet, capillary, or pipette printers.

As shown in FIG. 3G, second device 20B can be disposed in device location 30 on or over target substrate 10, for example using micro-transfer printing like the process for disposing first device 20A on target substrate 10. Second device 20B can therefore comprise a fractured (e.g., broken) or separated tether 24. To be disposed in device location 30 means that at least some portion of second device 20B overlaps or is within device location 30 over target substrate 10 or overlaps or is within the area in which first device 20A was disposed before removal. The overlap can be complete (for example if second device 20B has a second area over target substrate 10 that is at least equal to a first area of first device 20A or a location area of device location 30) or partial, e.g., overlapping only a portion of a location area corresponding to device location 30 or first device 20A over target substrate 10. The first area can be equal to the second area, the first area can be larger than the second area, or the first area can be smaller than the second area.

Second device 20B can be disposed horizontally offset from the location of removed first device 20A (e.g., in a direction parallel to a horizontal surface H of target substrate 10 on which devices 20 are disposed) or disposed rotated about a normal of horizontal surface H with respect to first device 20A, or both. If present, adhesive layer 12 can be cured (e.g., hard cured) and exposed portions of adhesive layer 12 can be removed (e.g., by oxygen plasma etching), as shown in FIG. 3H. Thus, according to embodiments of the present disclosure, first device 20A can comprise a connection post 54 and methods of the present disclosure can comprise connecting first device 20A to first contact location 31 by pressing connection post 54 to first contact location 31 by micro-transfer printing, second device 20B can comprise a connection post 54 and methods of the present disclosure can comprise connecting second device 20B to second contact location 32 by pressing connection post 54 to second contact location 32 by printing (e.g., micro-transfer printing), or both, thereby constructing interconnected system 90.

In some embodiments, an adhesive layer 12 can be disposed over target substrate 10 or in device location 30 on target substrate 10 to adhere first or second devices 20A, 20B to target substrate 10, as shown in FIGS. 3B-3H. In other embodiments, no adhesive layer 12 is used.

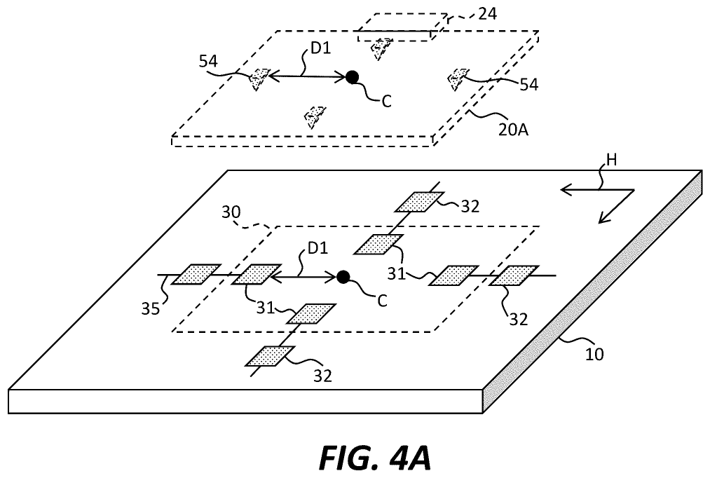

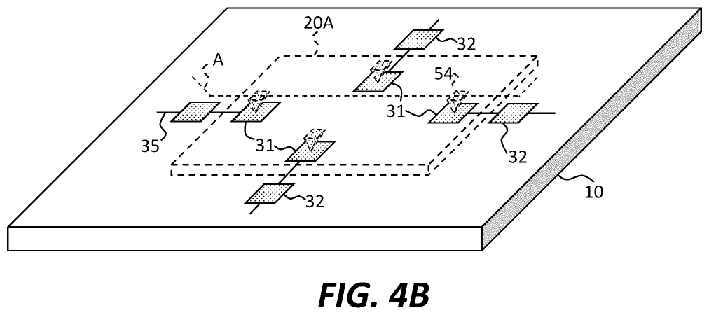

Embodiments of the present disclosure can comprise more than two first contact locations 31 and second contact locations 32. For example, and as shown in FIGS. 4A-5B, devices 20 can each have four (or more) electrical or optical connections 35 (e.g., to device contact pads 28) to control and respond to devices 20. Each electrical or optical connection can be associated with (connected to) a first contact location 31 (and first target contact pad 31) and, if device 20 fails, second contact location 32 (and second target contact pad 32). FIG. 4A is an exploded view illustrating a target substrate 10 with four sets of first and second target contact pads 31, 32 and a rectangular first device 20A with four connection posts 54 arranged around the perimeter of first device 20A. Connection posts 54 are each a first distance D1 from a center C of first device 20A (e.g., a geometric center or equidistant from opposing sides of rectangular first device 20A). Similarly, first target contact pad 31 can be a first distance D1 from a center C of device location 30 on target substrate 10 so that connection posts 54 of first device 20A can physically contact first target contact pads 31, as shown in FIG. 4B with first device 20A disposed in device location 30 of target substrate 10 and connection posts 54 connected to first target contact pads 31.

FIG. 5A is an exploded view illustrating a target substrate 10 with four sets of first and second target contact pads 31, 32 and a rectangular second device 20B with four connection posts 54 arranged around a perimeter of second device 20B. Connection posts 54 are each a second distance D2 from a center C of second device 20B (e.g., a geometric center or equidistant from opposing sides of rectangular second device 20B). Similarly, second target contact pad 32 can be a second distance D2 from a center C of device location 30 on target substrate 10 so that connection posts 54 of second device 20B can spatially contact second target contact pads 32 separately from first target contact pad 31, as shown in FIG. 5B with second device 20B disposed at least partially in device location 30 of target substrate 10 and connection posts 54 connected to second target contact pads 32. As described above, if first device 20A is connected to first contact locations 31 on target substrate 10 and fails under test, it can be removed and replaced with second device 20B connected to second contact locations 32 on target substrate 10 and connections 35 can optionally comprise cuts 36. First distance D1 and second distance D2 can be different distances and either can be larger or small than the other.

The process can be repeated multiple times, as illustrated in FIG. 5C, for example with four sets of first, second, third, and fourth contact locations 31, 32, 33, 34 (corresponding to first, second, third, and fourth target contact pads 31, 32, 33, 34) each located a different first, second, third, and fourth distance D1, D2, D3, D4 from a center C of device location 30. Embodiments of the present disclosure illustrate first contact locations 31 as closer to a center C of device location 30 and second contact locations 32 as farther from center C of device location 30. However, the relative positions of first and second contact locations 31, 32 over target substrate 10 are arbitrary and can be exchanged. For example, larger devices 20 can be disposed on target substrate 10 before or after smaller devices 20.

Thus, in interconnected systems 90 of the present disclosure, device location 30 can have a location area with a center C, first contact location 31 can be disposed at a first distance D1 from center C of device location 30, second contact location 32 can be disposed a second distance D2 from a center C of device location 30, and first distance D1 can be less than second distance D2, or first distance D1 can be greater than second distance D2. As discussed below, in some embodiments first distance D1 can be equal to second distance D2.

Thus, according to embodiments of the present disclosure, a target substrate 10 can comprise a third contact location 33 in or adjacent to device location 30 and a fourth contact location 34 in or adjacent to device location 30. Third contact location 33 can be spatially separate from first and second contact locations 31, 32 and third contact location 33 can be connected to first and second contact locations 31, 32 (e.g., with connections 35). Fourth contact location 34 can be spatially separate from third contact location 33 (and first and second contact locations 31, 32) and fourth contact location 34 can be connected to third contact location 33 (and first and second contact locations 31, 32 e.g., with connections 35). Embodiments can comprise removing the second device 20B and connecting a third device 20 to third contact locations 33. Embodiments can comprise removing the third device 20 and connecting a fourth device 20 to fourth contact locations 34. Thus, embodiments can generally include multiple target contact pads for each device 20 and multiple sets of the multiple target contact pads for multiple devices 20 sequentially disposed on target substrate 10 if each prior device 20 fails.

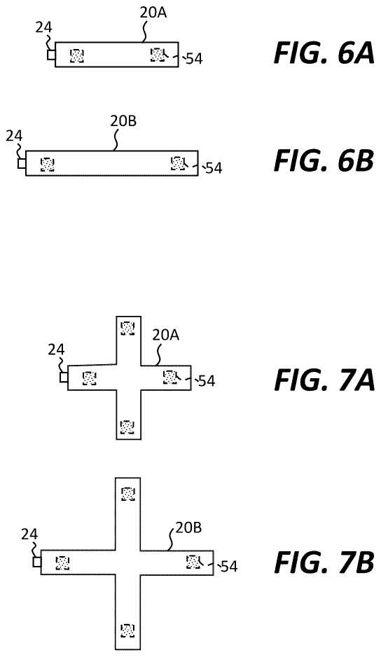

Devices 20 can have different sizes or shapes. FIG. 6A illustrates a rectangular device 20 (e.g., first device 20A) suitable for contacting first contact locations 31 and FIG. 6B illustrates a rectangular device 20 (e.g., second device 20B) that is larger than and geometrically similar to first device 20A so as to contact second contact locations 32 farther away from a center C of device location 30 than first contact locations 31. First and second devices 20A, 20B can have common functions or circuits 26.

FIG. 7A illustrates a plus-or cross-shaped device 20 (e.g., first device 20A) suitable for contacting first contact locations 31 and FIG. 6B illustrates a plus- or cross-shaped device 20 (e.g., second device 20B) that is larger than first device 20A so as to contact second contact locations 32 farther away from a center C of device location 30 than first contact locations 31. First and second devices 20A, 20B can have common functions or circuits 26. In general, there is no limitation to the shapes of devices 20 so long as different devices 20 can contact different target contact pads. In embodiments, first device 20A can have a first center C, second device 20B can have a second center C, and at least a portion of second device 20B extends farther from second center C than any portion of first device 20A extends from first center C. Thus, second device 20B can be geometrically similar to or larger than first device 20A.

Devices 20 in the embodiments of FIGS. 4A-5C are disposed over a common center C of device location 30. However, some embodiments can comprise second devices 20B that are arranged with a different orientation from first device 20A, for example offset in a horizontal direction H so that first and second devices 20A, 20B are not disposed over a common center C or for example are rotated differently with respect to a point on target substrate 10, or both. Thus, some embodiments of the present disclosure comprise disposing first device 20A on target substrate 10 with a first orientation and disposing second device 20B on target substrate 10 with a second orientation the same as or different from the first orientation. The different orientation can be a different offset, rotation or both offset and orientation, for example with respect to a center C of device location 30.

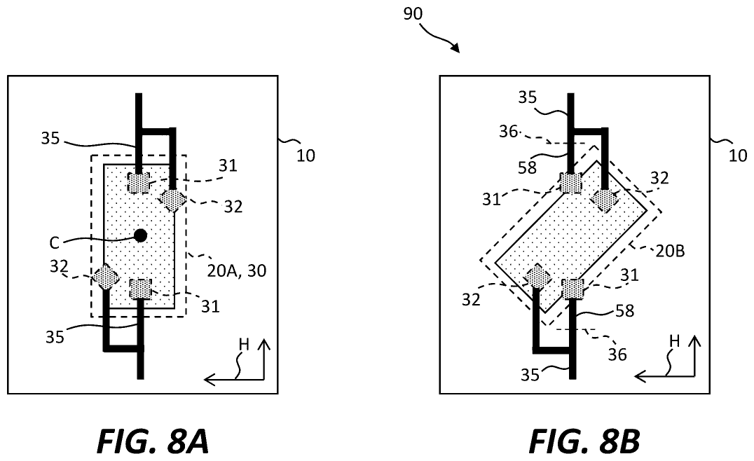

FIG. 8A illustrates a first device 20A with first target contact pads 31 connected to connections 35, for example as shown in FIG. 1A. However, second target contact pads 32 (second contact locations 32) are rotated about a center C (e.g., of device location 30 corresponding to the location of first device 20A). FIG. 8B illustrates second device 20B disposed on target substrate 10 but rotated about center C with respect to first device 20A and connected to second target contact pads 32, for example by 45 degrees (as shown) or 90 degrees. Connection 35 to first target contact pads 31 can have a cut 36 to prevent any connection to first target contact pads 31 from second device 20B.

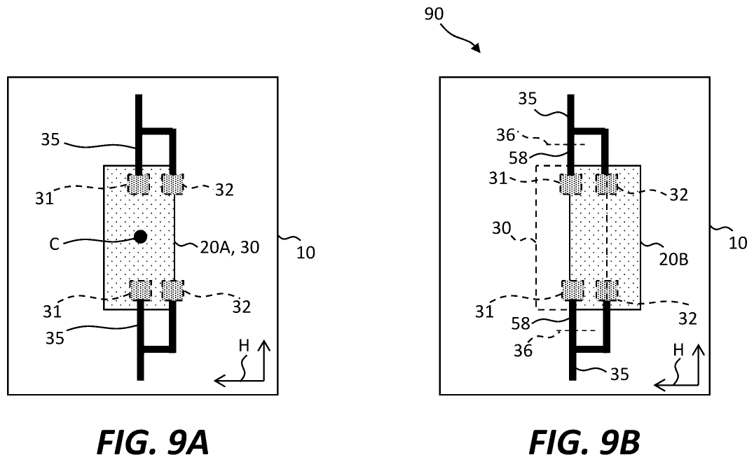

FIG. 9A illustrates a first device 20A with first target contact pads 31 connected to connections 35, for example as shown in FIG. 1A. However, second target contact pads 32 (second contact locations 32) are horizontally offset from a center C (e.g., of device location 30 corresponding to the location of first device 20A). FIG. 8B illustrates second device 20B disposed on target substrate 10 but offset from center C with respect to first device 20A and connected to second target contact pads 32. Connection 35 to first target contact pads 31 can have a cut 36 to prevent any connection to first target contact pads 31 from second device 20B. In embodiments, second device 20B can be both offset (as shown in FIG. 9B) and rotated (as shown in FIG. 8B) with respect to first device 20A.

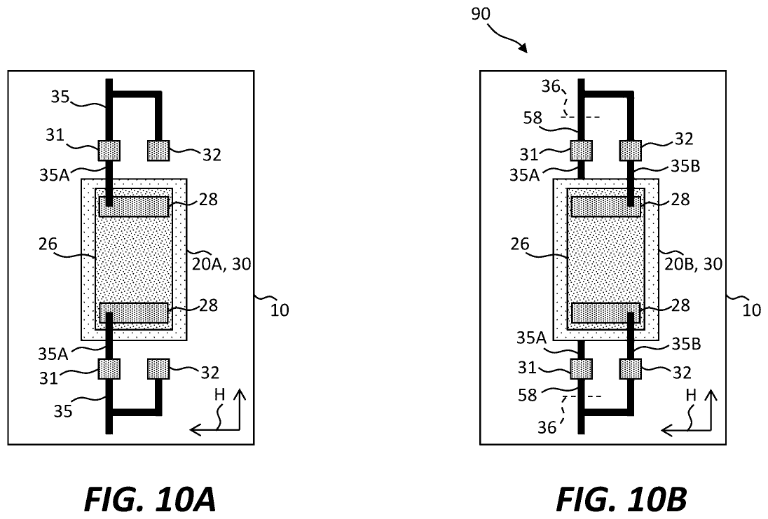

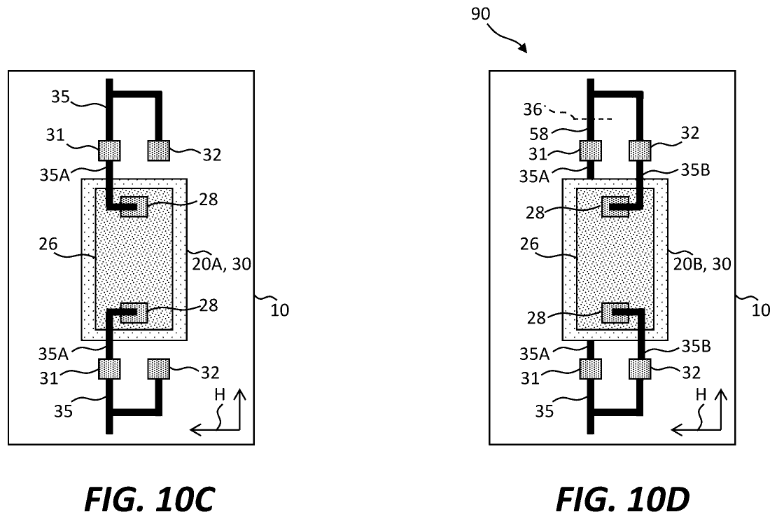

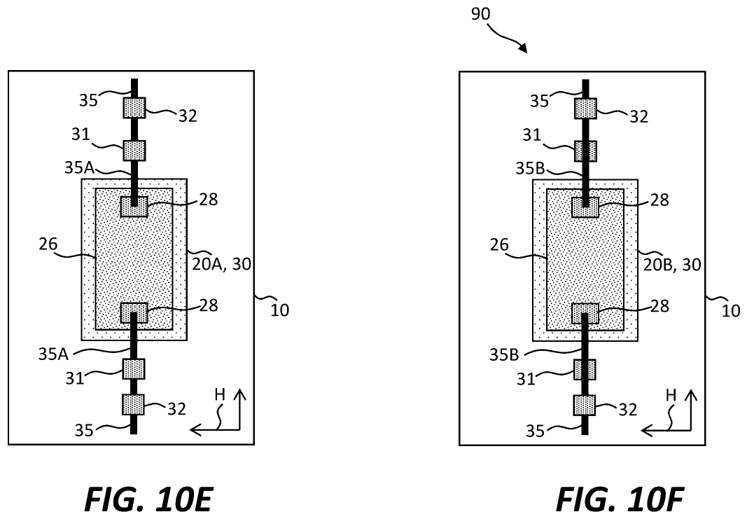

In some embodiments and as shown in FIGS. 10A and 10B, devices 20 can comprise device contact pads 28 that are sufficiently large to accommodate two different connections 35. As shown in FIG. 10A, a first device 20A with circuit 26 is disposed on target substrate 10 and connected with a first connection 35A to each device contact pad 28 and first contact location 31. If first device 20A fails, it can be removed, thus destroying any connection 35 (e.g., electrode 56 or first connection 35A) from first device 20A to first contact location 31, and a second device 20B having the same size is disposed in the same device location 30 (e.g., a substantially identical device 20 disposed in the same place) on target substrate 10. A second connection 35B can connect to second contact location 32. (In embodiments, first contact location 31 can be or comprise first connection 35A and second contact location 32 can be or comprise second connection 35B.) A cut 36 can be provided to disconnect first contact location 31 from second contact location 32. Thus, device 20 can comprise a device contact pad 28 having a device contact area and the device contact area can be large enough to connect to a first electrode 56 or first connection 35A connected to first contact location 31 and a second electrode 56 or second connection 35B connected to second contact location 32 (but not at a same time), and first electrode 56 and second electrode 56 (or first connection 35A and second connection 35B) are disposed in different locations. First and second electrodes 56 can be portions of connections 35. In some such embodiments, first device 20A and second device 20B can be substantially identical and have a same size, interfaces (connections), and function. This reduces the number of device 20 types, providing manufacturing and construction efficiencies and cost savings. Thus, in embodiments, first device 20A and second device 20B have a substantially same area, have a substantially similar shape, have a substantially similar form factor, are substantially geometrically similar, have a substantially same external structure, or any one or combination of these.

As shown in FIGS. 10C and 10D, a device contact pad 28 of device 20 can connect to first contact location 31 (if first device 20A is functional) or to second contact location 32 (with repair second device 20B if first device 20A is faulty) with first connection 35A or second connection 35B, respectively. In embodiments, connection 35 (or electrode 56) contact the same location on device contact pad 28 of first and second devices 20A, 20B but have an at least partly different path over devices 20 or target substrate 10, or both. FIG. 10C illustrates first device 20A with first connection 35A and FIG. 10D illustrates second device 20B with second connection 35B.

As shown in FIGS. 10E and 10F, first and second connections 35A and 35B can connect to a same location or portion of device contact pad 28 of device 20. After removal of first device 20A and replacement with second device 20B, second connection 35B can be disposed over or at least partly over first connection 35A and connection portion 58 and can extend beyond them to second contact location 32. FIG. 10E illustrates first device 20A disposed in device location 30 and FIG. 10F illustrates repair second device 20B in the same device location with second connection 32 extending over at least a part of first connection 35A (and connection portion 58). Such arrangements can reduce the area over target substrate 10 taken up by interconnected system 90.

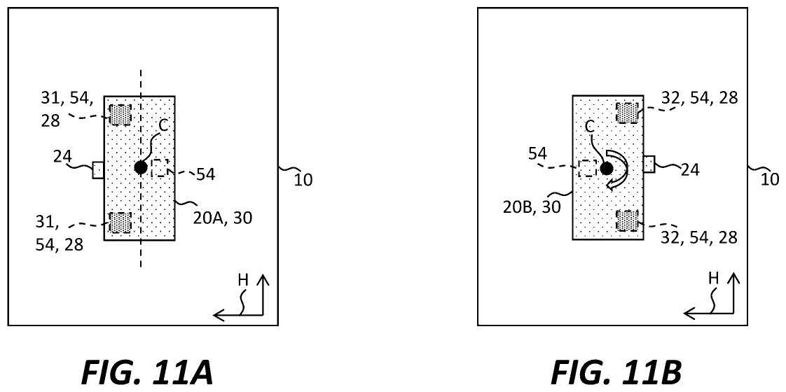

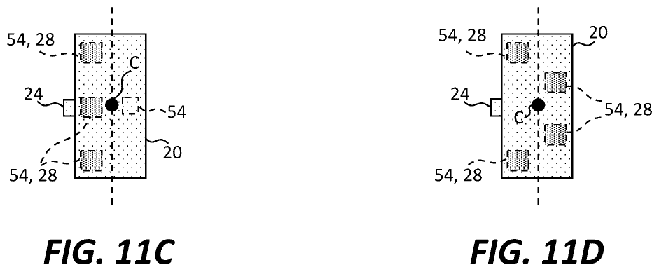

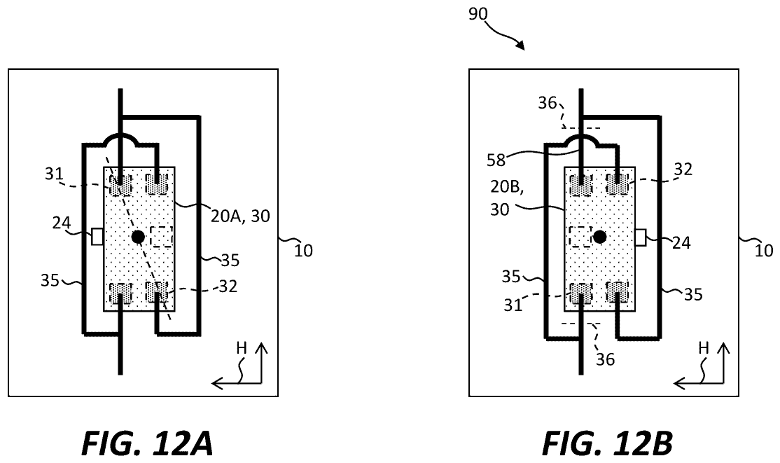

FIGS. 11A-12B illustrate some embodiments in which first device 20A and second device 20B can be substantially identical, have a same size and function, and can be disposed in the substantially the same location on or over target substrate 10. In such embodiments, first and second contact locations 31, 32 on target substrate 10 can be off-center (e.g., off-set) with respect to a center C of device location 30 or first and second devices 20A, 20B. Similarly, device contact pads 28 or connection posts 54 of a device 20 are disposed off-center with respect to a center C of device 20. In embodiments, off-center can mean not on a center line with respect to center C of device 20 (the center line is shown with a dashed line in FIG. 11A) and equidistant from a center C of device 20. FIG. 11A illustrates first device 20A disposed on target substrate 10 at device location 30 with off-center connections 35 to first contact locations 31. As shown in FIG. 11A, first contact locations 31, connection posts 54, or device contact pads 28 corresponding to first device 20A are disposed in, on, or over a left side of device location 30. However, if first device 20A is faulty, it can be removed and second device 20B disposed in the same device location 30 in a substantially same position but with a rotated orientation with respect to center C, device location 30, and target substrate 10, for example rotated 180 degrees about a normal of a horizontal surface H of target substrate 10 on or over which devices 20 are disposed through center C of device location 30 (or first device 20A) and as illustrated with the semicircular arrow. As shown in FIG. 11B, second contact locations 32, connection posts 54, or device contact pads 28 corresponding to second device 20B are then disposed in, on, or over a right side of device location 30 because of the rotation. Micro-transfer printing a device 20 in a rotated configuration is a straightforward and simple task for commercially available micro-transfer printers 16. FIGS. 11A and 11B omit connections 35 on target substrate 10 for clarity.

FIGS. 11A and 11B illustrate embodiments with two connection posts 54 or device contact pads 28. In some embodiments, there is no limit on the number of connection posts 54 or device contact pads 28 in a device 20. FIG. 11C illustrates embodiments with three off-center device contact pads 28 or connection posts 54 for a device 20. FIG. 11D illustrates embodiments with four off-center device contact pads 28 or connection posts 54 in device location 30. (Second devices 20B rotated in device location 30 corresponding to FIGS. 11C, 11D are not shown.) To ensure that no two connection posts 54 or device contact pads 28 in a device 20 (e.g., first device 20A, second device 20B, or both first and second devices 20A, 20B) are not in the same spatial location after in-place rotation (e.g., by 180 degrees) over target substrate 10, in embodiments no two of device contact pads 28 or connection posts 54 (or a center C of device contact pads 28 or connection posts 54) are disposed in a line through a center C of device 20 and equidistant from center C, e.g., device contact pads 28 or connection posts 54 are off-center. Correspondingly, first target contact pads 31 on target substrate 10 can be arranged in a similar off-center arrangement so that no first target contact pads 31 (or a center C of first target contact pads 31) are disposed in a line through a center C of device location 30 and equidistant from center C, e.g., first target contact pads 31 are off-center. Similarly, second target contact pads 32 on target substrate 10 can be arranged in a similar off-center arrangement so that no second target contact pads 32 (or a center of second target contact pads 32) are disposed in a line through a center C of device location 30 and equidistant from center C, e.g., second target contact pads 32 are off-center. In contrast, first target contact pad 31 is disposed in a line through a center C of device location 30 and equidistant from and on opposite side from center C with respect to second target contact pad 32, so that when second device 20B is rotated by 180 degrees with respect to first device 20A, second device 20B connection posts 54 or device contact pads 28 contact second target contact pads 32.

FIGS. 12A and 12B illustrate the structures of FIGS. 11A and 11B with connections 35 on target substrate 10. As shown in FIG. 12A (for first device 20A) and 12B (for second device 20B), upper left first contact location 31 is connected with connection 35 to bottom right second contact location 32 and upper right first contact location 31 is connected with connection 35 to bottom left second contact location 32 (unless cuts 36 are present as shown in FIG. 12B) so that first and second devices 20A, 20B are connected identically to connections 35 on target substrate 10. Thus, in some embodiments, second contact location 32 is disposed on an opposite side of center C of first device 20A or device location 30 from first contact location 31 so that first contact location 31 and second location 32 are symmetrically disposed about center C, e.g., so that a distance of first contact location 31 from center C is equal to a distance of second contact location 32 and, in some embodiments, second contact location 32 is rotated 180 degrees and opposite from first contact location 31 over target substrate 10. In embodiments, first contact location 31 and second contact location 32 are disposed in a line through center C and can be equidistant from center C (or other point in device location 30), e.g., as shown with the diagonal dashed line in FIG. 12A.

In such embodiments, first device 20A and second device 20B with off-center connections 35 (e.g., connection posts 54 or device contact pads 28) can be substantially identical and have a same size, interfaces (e.g., connections), and function. This reduces the number of device 20 types, providing manufacturing and construction efficiencies and cost savings. In embodiments having off-center connection posts 54, a dummy post can be provided as shown with the open dashed rectangles in FIGS. 11A-12B to provide mechanical stability and support when micro-transfer printing devices 20 to target substrate 10, for example to prevent devices 20 from falling over on target substrate 10 since connection posts 54 can be off-center with respect to devices 20. Multiple dummy posts can be provided (on either device 20 or target substrate 10), as necessary or useful. Thus, in embodiments, devices 20 or target substrate 10 can comprise three or more connection posts 54. Some of connection posts 54 can be dummy connection posts 54 (e.g., non-functional or provided for mechanical stability).

Connections 35 can be constructed in a variety of ways and according to various embodiments of the present disclosure. In some embodiments, connections 35 are made by evaporatively (or sputtering or coating, e.g., spin or spray coating) a connection material (e.g., electrically conductive metal or transmissive high-index optical material) and then photolithographically patterning the connection material to form connections 35, for example as shown in FIGS. 2B, 2D, that are connected to device 20 with connection posts 54 and photolithographically constructed electrodes 56. In some embodiments, electrodes 56 are photolithographically constructed with thin-film electrodes 56 that extend from device contact pads 28 to connections 35, as shown in FIG. 13A. Such photolithographic methods typically require relatively expensive masks that are suitable for making many predefined connections 35. In other embodiments, connections 35 and electrodes 56 can be made on an as-needed basis using print-on-demand methods, e.g., such as pattern-wise deposition of materials over patterned dielectric structures, as also shown in FIG. 13A (where electrodes 56 are pattern-wise deposited conductors) and corresponding to FIGS. 10A and 10B. Electrode 56 can be considered a part of connection 35 since it connects device contact pad 28 of circuit 26 in device 20 to connections 35. Commercial tools exist for forming both electrical connections 35 and optical connections 35, e.g., by extruding and/or jetting curable material (e.g., one or more materials) with conductive particles that can be cured to form an electrical connection 35 or extruding and/or jetting curable material (e.g., one or more materials) with relatively high index transmissive material (that can be coated with an optically reflective layer) to form an optical connection 35.

In embodiments of the present disclosure where connections 35 or electrodes 56 are made individually and on-demand (e.g., as part of a repair process) and devices 20 must be insulated from connections 35 or electrodes 56 (e.g., electrically or optically), dielectric structures 52 can likewise be individually deposited on-demand under computer control (e.g., a micro-controller), for example by pattern-wise depositing a curable liquid around device 20 and optionally over a portion of device 20, for example adjacent to device 20, in contact with sides of device 20 (at least partially orthogonal to a target substrate 10 surface on which devices 20 are disposed), or partially over device contact pads 28. The curable liquid (e.g., a cross-linkable resin) can be cured to form dielectric structures 52 insulating device 20 and pattern-wise connections 35 can then be disposed over dielectric structures 52 and in contact with device contact pad 28 and second target contact pad 32. The on-demand construction of dielectric structures 52 is at least partly enabled by thin micro-devices 20, so that the step height from target substrate 10 to a top side of micro-device 20 opposite target substrate 10 is relatively small, e.g., ten, five, four, two, or one micron, and relatively little material is needed for dielectric structures 20 and capillary forces can facilitate the construction of dielectric structures 52.

In some embodiments using electrical connections 35, bond wires 55 can act as electrodes 56 to electrically connect a device contact pad 28 of device 20 to a connection 35, as shown in FIG. 13B. In this case, bond wires 55 can be considered a part of connection 35 since it connects device contact pad 28 of circuit 26 in device 20 to connections 35.

In some embodiments, such as those shown in FIG. 13C, connection posts 54 in first and second contact locations 31, 32 can be disposed on target substrate 10 and a corresponding device contact pad 28 disposed on device 20 to connect circuit 26 of device 20 to first or second contact locations 31, 32, for example using micro-transfer printing. Such a connection post 54 disposed on target substrate 10 can be at least a portion or all of first contact location 31 or first target contact pad 31 and damage to this target-substrate connection post 54 can comprise at least a portion or all of connection portion 58. Embodiments of the present disclosure that illustrate connection posts 54 extending from a device 20 to a contact pad or location on target substrate 10 can equally be implemented with connection posts 54 extending from target substrate 10 to device contact pads 28 of devices 20, e.g., on a bottom side of device 20 as shown in FIG. 13C. Dummy connection posts 54 can also be provided on target substrate 10 to provide mechanical stability to devices 20 when micro-transfer printing devices 20 to target substrate 10. In any of these cases, device 20 can be disposed directly on target substrate 10 (as shown in FIGS. 13A, 13B, 13C), or directly on a module substrate 11 that is disposed directly on target substrate 10 and is non-native to (e.g., separate, different from, and independent of) target substrate 10, as shown in FIG. 13D. (As used herein, directly on can include on an adhesive layer 12 on module substrate 11 or target substrate 10.) Module substrates 11 can be connected to target substrate 10 using structures and methods similar to those for connecting device 20 to module or target substrates 11, 10.

Micro-transfer printing devices 20 from a device source wafer to a target or module substrate 10,11 provides a structural advantage in embodiments of the present disclosure because micro-transfer-printed structures can have a very thin substrate (e.g., no greater than fifty, twenty, ten, five, two, or one micron). Such thin substrates reduce a step height from the top of a micro-transfer-printed first substrate to a second substrate on which the first micro-transfer-printed substrate is disposed, enabling robust photolithographically or pattern-printed connections 35 (e.g., electrodes 56 or at least portions of connections 35) from the first micro-transfer-printed substrate to the second substrate, as shown in FIGS. 10A, 10B, and 13A.

Thus, according to embodiments of the present disclosure, an interconnected system 90 can comprise a target substrate 10 having a device location 30, a first contact location 31 in, on, or adjacent to device location 30, and a second contact location 32 in, on, or adjacent to device location 30 that is spatially separate from the first contact location 31. A second device 20B can be disposed in the device location 30 (e.g., after removing a first device 20A from device location 30). At least a portion of a first connection 35A can be disposed on or in the first contact location 31 and a second connection 35B connecting the second contact location 32 to second device 20B.

In embodiments, first contact location 31 can be connected to second contact location 32 (e.g., electrically or optically). Connection portion 58 of a first connection 35A can be a portion of a thin-film electrical or optical connection, an indentation, divot, or hole in a target contact pad (e.g., first target contact pad 31) or connection 35, a portion of a pattern-printed conductive or transmissive wire, a portion of a photolithographically defined wire, or a portion of a wire bond in first contact location 31. A conductive wire can be an electrically conductive wire, and a transmissive wire can be an optically transmissive waveguide or optical fiber.

In embodiments, first contact location 31 can be disposed with a same or different rotation or orientation as second contact location 32 with respect to device location 30 or target substrate 10. In embodiments, first contact location 31 or first device 20A can be disposed offset in horizontal direction H with respect to second contact location 32 or second device 20B or with respect to device location 30 or target substrate 10, for example horizontally offset over a surface of target substrate 10 on which device location 30 or device 20 is disposed. In embodiments, first contact location 31 or first device 20A can be disposed rotated about an axis orthogonal to horizontal direction H with respect to second contact location 32 or second device 20B or with respect to device location 30 or target substrate 10, for example rotated horizontally over a surface of target substrate 10 on which device location 30 or device 20 is disposed.

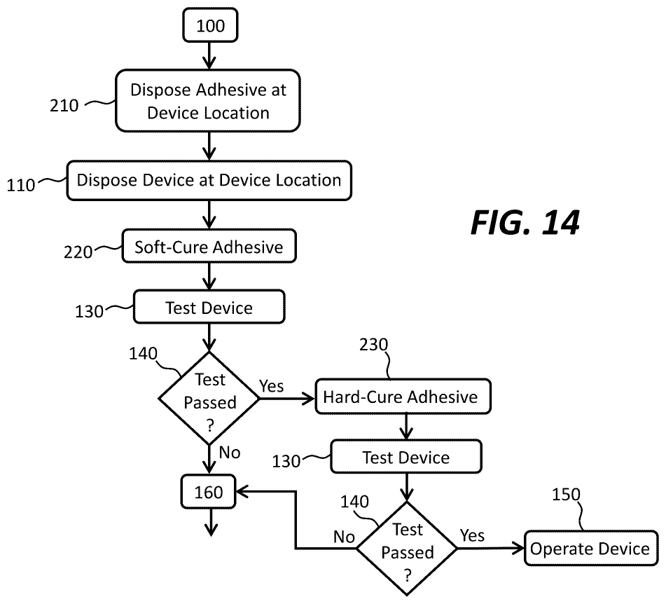

In some embodiments and as shown in FIGS. 3A-3H, interconnected system 90 can comprise an adhesive 12 for adhering devices 20 to target substrate 10 (or a module substrate 11). Devices 20 can be tested before curing adhesive 12, after soft curing adhesive 12, or after hard curing adhesive 12. Device 20 can be most easily removed before curing and can be removed more easily after soft curing and before hard curing than after hard curing. However, devices 20 can move somewhat during curing, potentially affecting a connection to devices 20, so a yield or performance tradeoff can exist between the time at which devices 20 are tested (before or after soft or hard curing) and when they are removed (if faulty) before or after soft or hard curing. Tested performance of device 20 is more likely to be incorrect if conducted before curing but device 20 removal is then easier. Tested performance of device 20 is more likely to be correct if conducted after curing but device 20 removal is then harder. As illustrated in the flow diagram of FIG. 14, adhesive 12 can be disposed in device location 30 on target substrate 10 (or module substrate 11) in step 210, device 20 disposed in at least a portion of device location 30 in step 110, and adhesive 12 can be soft cured in step 220, after which device 20 is tested in step 130. If the test is passed (step 140), adhesive 12 is hard cured in step 220 and device 20 can be (optionally) retested in step 130. If the retest is passed in step 140, device 20 can be put into operation in step 150. If either of the two tests (steps 140), either immediately after soft cure (step 220) or after hard cure (step 230), device 20 is removed in step 160 and the replacement process can be begin (e.g., in step 170 as shown in FIG. 1).

In some embodiments of the present disclosure, interconnected system 90 comprises multiple devices 20 disposed on target substrate 10. At least some of devices 20 can be first devices 20A that do not fail under test and remain adhered to target substrate 10 with a first adhesive 12 having a first cure temperature. However, in embodiments some but not all of first devices 20A do fail and are replaced with repair second devices 20B. Embodiments of the present disclosure can comprise removing only failed first devices 20A (for example by mechanical or ablation means) and any exposed first adhesive 12 (e.g., first adhesive 12) for example with a field etch of exposed first adhesive 12 material to clean device location 30. A subsequent second adhesive layer 12 can be disposed in device location 30 (e.g., by unpatterned spin coating, patterned or unpatterned spray coating, or pattern-wise deposition using a pattern-printing device) before disposing second device 20B in device location 30 and cured after disposing second device 20B in device location 30. If a first adhesive 12 adhering first device 20A to target substrate 10 is cured at the first temperature and a second temperature equal to or greater than the first temperature is used to cure second adhesive 12 to adhere second device 20B to target substrate 10, first adhesive 12 can reflow and move first devices 20A remaining on target substrate 10, causing first devices 20A that initially passed testing in step 130 to subsequently move, possibly disconnect from first target contact pads 31, and fail. Therefore, in embodiments the second temperature is less than the first temperature so that when second adhesive 12 is cured, first adhesive 12 does not reflow at the lower temperature so that first devices 20A do not move and do not fail. In some embodiments, second device 20B is disposed onto target substrate 10 without a second adhesive 12. In some embodiments, first adhesive 12 is cured at a first temperature, second device 20B is disposed onto target substrate 10 without a second adhesive 12, and second device 20B and target substrate 10 are annealed at an anneal temperature less than the first temperature, adhering second device 20B to target substrate 10 without reflowing adhesive 12 or moving remaining first devices 20A. Two different adhesives 12 can be used or cured using different techniques (e.g., ultra-violet exposure and heat exposure). In some embodiments a same adhesive 12 is used to adhere both first devices 20A and second devices 20B but are cured using different methods or are cured using at least one method that does not cause reflow. In some embodiments, no adhesive 12 is used and devices 20 are annealed to target substrate 10, for example multiple times, e.g., a first time for first devices 20A and a second time for repair second devices 20B.

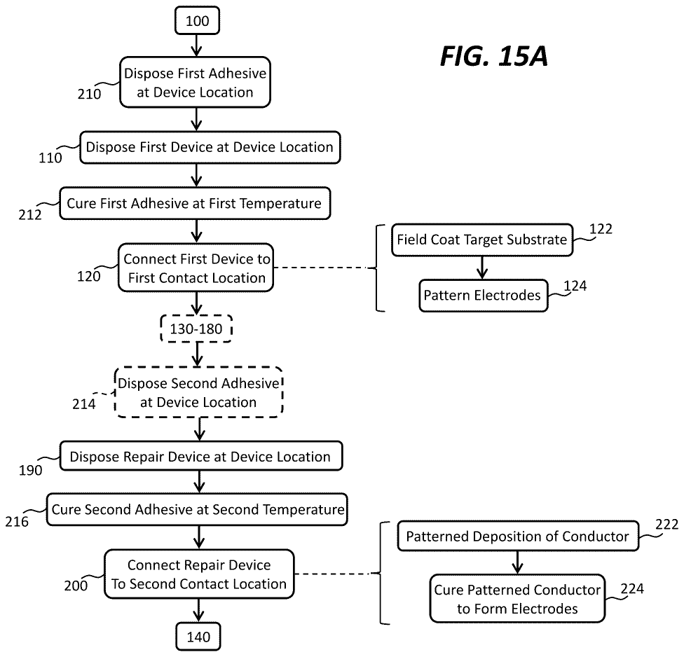

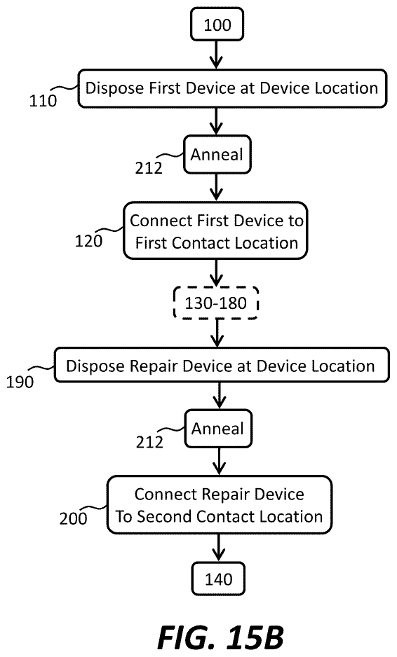

FIG. 15A illustrates methods of the present disclosure. A shown in FIG. 15, a target substrate 10 is provided in step 100 and coated with a first adhesive 12 in step 210. A device 20 (e.g., first device 20A) can be disposed (e.g., by micro-transfer printing) into device location 30 and adhered to target substrate 10 in step 110. First adhesive 12 can then be cured in step 212, for example at a first cure temperature, and connected to first contact location 31 in step 120. In embodiments, the connection (e.g., electrode 56 or connection 35) can be made by first depositing an unpatterned layer of conductive material (e.g., a metal deposited by evaporation or sputtering) in step 122 and then photolithographically patterning the unpatterned layer in step 124 to form electrodes 56 or connections 35. If the disposed first device 20A fails an operational test, it can be removed and device location 30 cleaned in steps 130-180, as discussed with respect to FIG. 1. In step 214, second adhesive 12 can be optionally disposed in device location 30 and a repair second device 20B disposed in step 190 at least partly in device location 30. Optional second adhesive 12 can then be cured, for example at a second cure temperature less than the first cure temperature, to prevent first adhesive layer 12 from reflowing. connected to first contact location 31 in step 120. A connection (e.g., electrode 56 or connection 35) can be made in step 200 between second device 20B and second contact location 32. In embodiments, the connection (e.g., electrode 56 or connection 35) can be made by pattern-wise depositing a conductor or transmitter in step 222 and then curing the conductor or transmitter in step 224 to form electrodes 56 or connections 35. For example, material can be pattern-wise deposited and then cured, for example with heat or radiation, to form an electrically conductive or optically transmissive connection 35. Since the failure of first device 20A cannot be predicted, disposing and connecting repair second device 20B can be done on an individual basis, e.g., with micro-transfer printing individual repair second devices 20B and individually forming connections 35 to second contact location 32.

Since, in general, relatively many first devices 20A do not fail, using photolithographic methods and materials to connect first devices 20A in common steps can be efficient. Since, in some embodiments, relatively few first devices 20A fail and relatively only small numbers of second devices 20B need later be disposed and connected on target substrate 10, using individual and separate pattern-wise methods and materials to connect second devices 20B can be efficient. Using a photolithographic method and material enables the construction of many electrodes 56 or connections 35 in one step and is very efficient where many electrodes 56 or connections 35 on target substrate 10 are needed but requires a fixed location for electrodes 56 or connections 35 defined by a pre-made mask. In some embodiments, electrodes 56 or connections 35 can be made individually, for example one at a time, by pattern-wise depositing materials that are cured to form conductive or transmissive electrodes 56 or connections 35. Such electrodes 56 or connections 35 can be made under software control (e.g., on an as-needed basis controlled by a micro-controller operating a pattern-printing device) but are relatively slow.

In some embodiments, an adhesive 12 is not used and devices 20 are transfer printed directly to target substrate 10 and adhered using van der Waals forces. Such adhesion can be increased by annealing. As shown in FIG. 15B, devices 20 deposited in step 110 are annealed at a suitable high temperature in step 212 and then connected in step 120. If a first device 20A fails (steps 130-180), it can be replaced in step 190 and annealed in step 212 and then connected in step 200. Repeated annealing steps for good first devices 20A do not reduce adhesion.

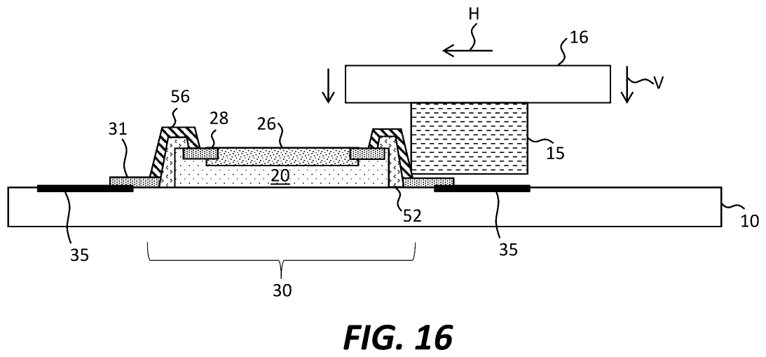

In embodiments of the present disclosure, a faulty first device 20A can be removed from target substrate 10 by any one or combination of mechanical scraping, mechanical grinding, mechanical cutting, particle beam ablation or cutting, laser (electromagnetic radiation) ablation or cutting, or vacuum extraction. A transfer printer 16 can enable various versions of such removal using different stamps or stamp posts 14 such as a hardened stamp or hardened stamp post 15, as illustrated in FIG. 16. The hardened stamp 15 can comprise a hardened stamp post 15 that is more rigid, harder, stiffer, or less compliant than a stamp post 14 used for transfer printing but the same transfer printer 16 can be used to move the hardened stamp 15 in various directions to contact first device 20A and remove first device 20A from target substrate 10 (e.g., perform step 160 of FIG. 1). In embodiments, transfer printer 16 can move hardened stamp 15 until it is just above and optionally not in contact with target substrate 10 and adjacent or near to first device 20A. Transfer printer 16 then moves hardened stamp 15 until it is in contact with first device 20A and then presses against first device 20A to move first device 20A from device location 30. As first device 20A can be adhered to target substrate 10 in device location 30, a greater force with a hardened stamp 15 than is used to print first device 20A to target substrate 10 can be used to remove first device 20A from target substrate 10.

In various embodiments, various methods of contacting first device 20A can be used. In some embodiments and as shown in FIG. 16, transfer printer 16 moves hardened stamp 15 in a horizontal direction H parallel to a surface of target substrate 10 on which first device 20A is disposed to press hardened stamp 15 against a side (e.g., a side partially orthogonal to in a or vertical direction V at least partially orthogonal to horizontal direction H) of first device 20A or structures formed on the side of first device 20A to crack any adhesive 12 adhering first device 20A to target substrate 10 or form a delamination front between first device 20A and target substrate 10 that progresses across a bottom side of first device 20A adjacent to target substrate 10 to loosen first device 20A from target substrate 10. Since sizes of the various elements of adhered device 20 can be a few microns (or less), the strength and adhesion of device 20 can be relatively small compared to the force brought to bear against device 20 by hardened stamp 15.

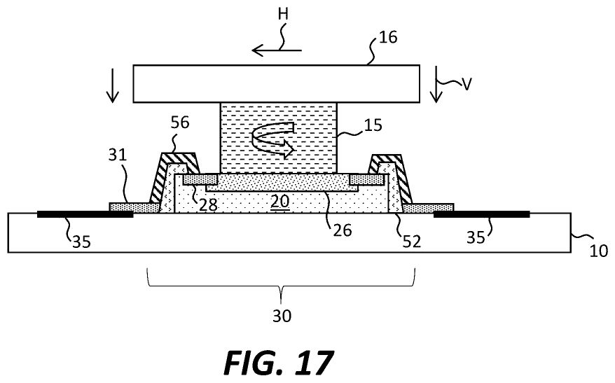

In some embodiments and as shown in FIG. 17, transfer printer 16 moves hardened stamp 15 in a vertical direction V orthogonal to a surface of target substrate 10 on which first device 20A is disposed to press hardened stamp 15 against a top (e.g., a side parallel to and opposite target substrate 10) of first device 20A or structures formed on the top of first device 20A. Transfer printer 16 then rotates hardened stamp 15 to crack any adhesive 12 adhering first device 20A to target substrate 10 or form a delamination front between first device 20A and target substrate 10 that progresses across a bottom side of first device 20A adjacent to target substrate 10 to loosen first device 20A from target substrate 10. The rotation can be an oscillating rotation in alternating clockwise and counterclockwise directions. Such a motion is provided in available commercial transfer printers 16. In some embodiments, hardened stamp 15 spins to grind or drill into first device 20A or to provide friction against first device 20A that can loosen first device 20A from target substrate 10.

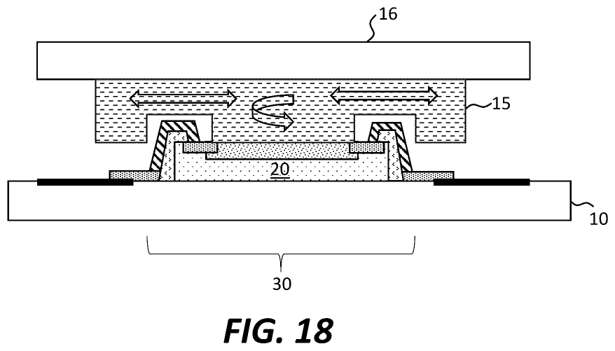

In some embodiments and as shown in FIG. 18, hardened stamp 15 can have a patterned distal surface (surface farthest from transfer printer 16) to provide increased friction against first device 20A, particularly when first device 20A has a complementary topographical (e.g., non-planar) surface. Thus, hardened stamp 15 can mechanically lock in against structures on the top of first device 20A to increase friction and horizontal or rotational pressure against first device 20A. In some embodiments, the patterned distal surface comprises a cutting structure (e.g., a blade or scraper) operable to cut first device 20A. In some embodiments, transfer printer 16 can move hardened stamp 15 in horizontal direction H in addition to or in place of a rotation when in contact with the top of first device 20A, as shown with the arrows in FIG. 18. If hardened stamp 15 has sufficiently sharp topographic features on a distal end of a hardened stamp post 15, the distal end can cut into or grind a faulty first device 20A, for example with an oscillatory rotation or horizontal movement in contact with first device 20A.

Hardened stamp 15 can comprise a single hardened stamp post 15 to contact a single first device 20A at a time (where interconnected system 90 comprises multiple devices 20) to control the rotation of hardened stamp 15. Single-post hardened stamps 15 are especially useful because it can be difficult or impossible to predict which first devices 20A will fail (otherwise, in embodiments they are not printed) and can then enable removing single failed first devices 20A.

As adhesive layers 12 for micro-transfer-printed first devices 20A can be only some nanometers thick, friction by hardened stamp 15 can crack or otherwise delaminate adhesive 12 and loosen adhesion between first device 20A and target substrate 10.

In some embodiments, energetic particles (e.g., focused ion beams) or high-energy electromagnetic radiation (e.g., lasers) can be directed against faulty first devices 20A to diminish their structural integrity, rendering faulty first devices 20A easier to dislodge from target substrate 10. Such bombardment can be done, for example, independently of or in addition to (e.g., prior to) mechanical removal using hardened stamp 15.

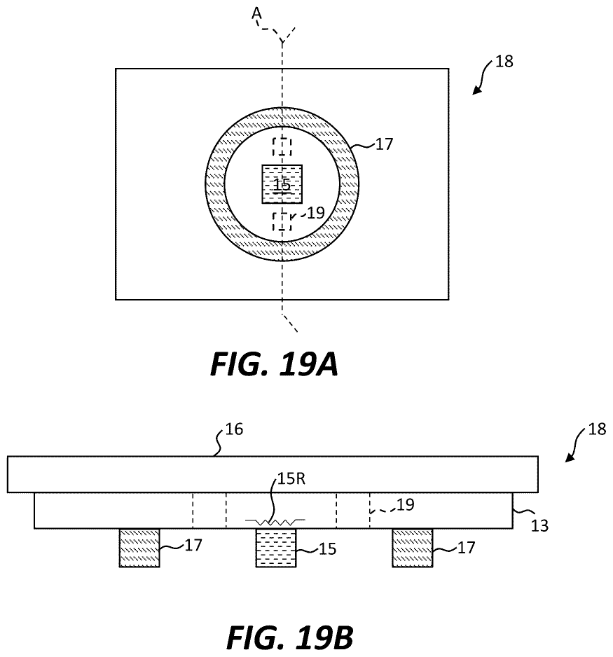

Some embodiments of the present disclosure can use a removal tool 18 (rather than or as a transfer printer 16 with a hardened stamp 15) comprising a pin 15 (e.g., a hardened stamp post 15) together with other structures to inhibit any particulate contamination resulting from dislodging faulty first device 20A from target substrate 10. Such inhibition structures can comprise, for example, a wall 17 or shield surrounding or partially surrounding pin 15, as shown in FIGS. 19A and 19B. The wall 17 or shield can confine any particulate contamination within removal tool 18 and the area surrounding pin 15 can be subject to low-air pressure (e.g., lower than an atmospheric pressure surrounding interconnected structure 90, such as a vacuum or partial vacuum provided by a vacuum apparatus, e.g., a vacuum port 19) to entrain any particles in a gas (e.g., air) flow and remove the particles from target substrate 10. The atmosphere can be provided through gaps in wall 17 or provided within a surrounding wall 17. If the atmosphere is provided through a gap in wall 17, stamp motion can be at least partly away from the gap so that any particles will more likely be trapped by wall 17. Surrounding wall 17 can be less rigid than pin 15 or transfer printer 16, for example comprising PDMS, for example to accommodate non-planar surface structures on target substrate 10 and to avoid damaging any such structures when pin 15 is moved horizontally or rotationally on the target-substrate surface. In some embodiments, hardened removal stamp 15 or pin 15 of removal tool 18 can be heated with a pin heating element 15R. Heating pin 15 can soften or reflow an adhesive 12 adhering first device 20A to target substrate 10 or can heat materials with different coefficients of thermal expansion, reducing their adhesion with different amounts of movement relative to each other.

Thus, according to embodiments of the present disclosure, a method of repairing a micro-transfer-printed system (e.g., interconnected system 90) can comprise providing a target substrate 10 having a target-substrate surface, a device location 30, and a first contact location 31 in, on, or adjacent to device location 30. A first device 20A can be disposed onto the target-substrate surface at device location 30 using micro-transfer printing. First device 20A can be connected to first contact location 31 and tested. If the test fails, a removal tool 18 contacts first device 20A to remove first device 20A from target substrate 10. Once first device 20A is removed, device location 30 cleaned, and first contact location 31 isolated, methods can comprise disposing repair second device 20B on the target-substrate surface at least partly in device location 30 using micro-transfer printing.

In some embodiments, removal tool 18 can comprise a transfer printer 16 using a hardened stamp 15 or hardened stamp post 15 (e.g., a removal stamp 15 or removal pin 15) to contact first device 20A, for example by any one or combination of pressing removal stamp 15 horizontally against a side of first device 20A that extends at least partly orthogonally to the target-substrate surface, vertically pressing removal stamp 15 against a surface of first device 20A opposite the target-substrate surface (e.g., a top side of first device 20A) and moving removal stamp 15 at least partly parallel (e.g., horizontally) to the target-substrate surface, and pressing removal stamp 15 against a surface of first device 20A opposite the target-substrate surface and rotating removal stamp 15 about an axis at least partly orthogonal to the target-substrate surface. Hardened stamp 15 or hardened stamp post 15 can be a removal pin 15, for example a metal pin or a pin comprising a cured or hardened resin, PDMS, or other polymer for example a metal-coated polymer or other polymer coated with a hard material. Removal pin 15 can be disposed on or extend away from a rigid support 13, such as glass, silicon, quartz, or metal. Removal pin 15 can be heated with pin heating element 15R (e.g., with an electrically resistive element), for example to heat first micro-device 20A and soften adhesive 12 (e.g., reflow adhesive 12 for example reflow soft-cured adhesive 12) to loosen first micro-device 20A from target substrate 10. Since embodiments of the present disclosure can be made by micro-transfer printing devices 20 having dimensions in the micron range, removal tool 18 (e.g., comprising a removal stamp 15, pin 15, or hardened stamp post 15) can have a cross section with an extent no greater than two hundred, one hundred, fifty, twenty, ten, five, two, or one micron, e.g., in thickness (in a direction orthogonal to a surface of rigid support 13 from which removal pin 15 extends) or a length or width (in a direction parallel to the surface of rigid support 13). In embodiments, removal pin 15 has a distal surface away from rigid support 13 that has a topographic, non-planar structure. Removal tool 18 can comprise a vacuum apparatus surrounding, partially surrounding, or adjacent to removal pin 15. The vacuum apparatus can comprise vacuum port 19 and wall 17 at least partially surrounding removal pin 15 and vacuum port 19 and wall 17 can be more flexible than rigid support 13 or removal pin 15.

Because devices 20 can be disposed on target substrate 10 with micro-transfer printing, devices 20 can be very thin with a small step height over target substrate 10 and can therefore be connected using patterned deposition that can accommodate the small step height. A greater step height can cause breaks or gaps in a patterned deposition. Therefore, some embodiments of the present disclosure can comprise an interconnected system 90 comprising a target substrate 10 having a target-substrate surface and a device 20 disposed on the target-substrate surface. Device 20 can have a thickness orthogonal to the target-substrate surface of no greater than one hundred, fifty, twenty, ten, five, two, or one micron and a device contact pad 28 disposed on a contact side of device 20 opposite the target-substrate surface. A patterned electrical or optical connection 35 (or electrode 56) can be pattern-wise disposed on the target-substrate surface and can continuously extend from the target-substrate surface onto the contact side in electrical or optical contact with device contact pad 28. The patterned electrical or optical connection 35 or electrode 56 can comprise a cured or annealed material, for example comprising sintered metal nanoparticles. Thus, the patterned electrical or optical connection 35 or electrode 56 can comprise a conductive material (e.g., metal nanoparticles) distributed in the cured material (e.g., a cured resin or epoxy). Because devices 20 can be micro-transfer-printed devices 20, they can comprise a broken or separated tether as a consequence of micro-transfer printing.

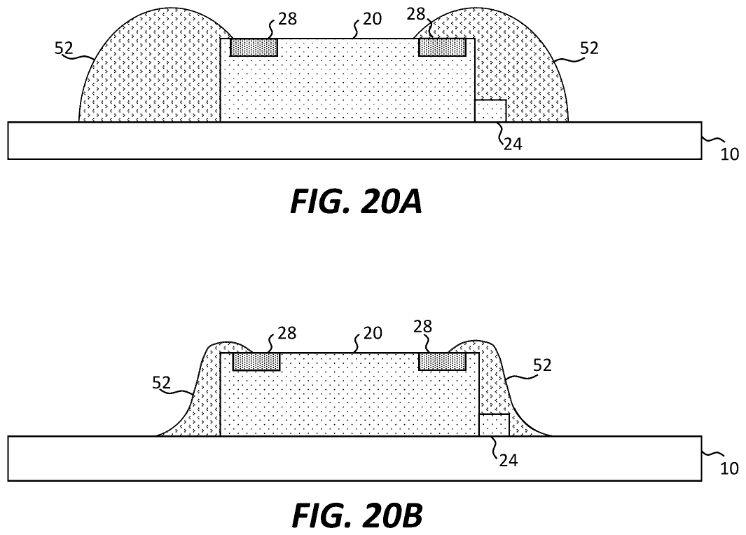

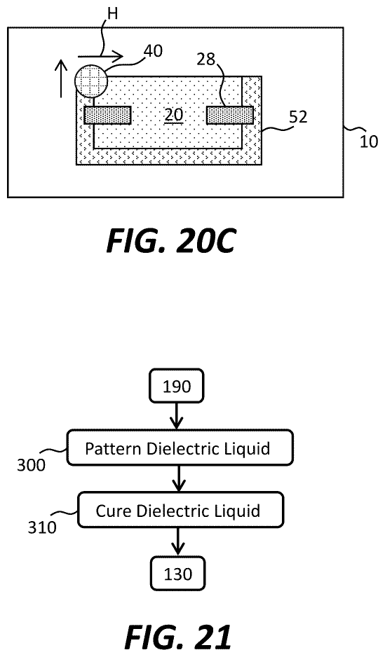

Interconnected systems 90 of the present disclosure can be constructed using micro-transfer-printed micro-devices 20 on a target substrate 10 and insulated using pattern-printed dielectric 52 materials disposed around a perimeter of micro-devices 20, for example as illustrated in the cross sections of FIGS. 20A and 20B, the plan view of FIG. 20C, and the flow diagram of FIG. 21. Micro-device 20 can be a bare die. FIG. 20A illustrates a bank of uncured (e.g., liquid) dielectric 52 material, such as a resin, epoxy, photoresist or other curable material, for example comprising cross-linking materials in a polymer, disposed in step 300 around a perimeter of micro-device 20 printed on target substrate 10 provided in step 190. As shown in FIG. 20C, dielectric 52 material can be disposed using a pattern-printing device 40 such as an inkjet, capillary, pipette or other pattern-printing device 40 to dispose curable dielectric liquids. FIG. 20C illustrates pattern-printing device 40 moving around a perimeter of micro-device 20 to dispose curable liquid dielectric 52. Once cured in step 310 and as shown in FIG. 20B, liquid dielectric 52 can shrink and form a patterned coating wicked over at least portions of edges around the perimeter of micro-device 20. Electrodes 56 or connections 35 can then be pattern-printed as a liquid on cured dielectric structure 52 to connect to device contact pad 28, as shown in FIG. 13A and in step 222 of FIG. 15A and then cured to form patterned connections 35 in step 224. Cured dielectric structure 52 can also serve to additionally adhere micro-device 20 to target substrate 10.

Thus, according to embodiments of the present disclosure, a method of connecting a micro-transfer-printed micro-device 20 can comprise providing a target substrate 10 having a target-substrate surface, a micro-device 20 comprising a device contact pad 28, a micro-transfer printer 16, and a pattern-printing device 40, disposing micro-device 20 on the target-substrate surface using micro-transfer printer 16, disposing a pattern of curable liquid dielectric 52 around at least a portion of a perimeter of micro-device 20 using pattern-printing device 40, and curing the curable liquid dielectric 52 to form a dielectric structure 52. Some embodiments include disposing curable liquid dielectric 52 using pattern-printing device 40 at least partially on at least a portion of the target-substrate surface. Once disposed in a pattern, curable liquid dielectric 52 can be cured to form a cured dielectric structure 52. Electrodes 56 or connections 35 can be constructed by pattern-wise deposition of a curable liquid conductor (e.g., conductive ink) using pattern-printing device 40 (either the same pattern-printing device 40 or a different pattern-printing device) over at least a portion of target-substrate surface, dielectric structure 52, and device contact pad 28, and then curing the curable liquid conductor.

Some embodiments of an interconnected system 90 can comprise a target substrate 10 having a target-substrate surface and a micro-device 20 disposed on the target-substrate surface. Micro-device 20 can comprise a fractured or separated tether 24 as a consequence of micro-transfer printing micro-device 20 to target substrate 10. A cured dielectric material 52 can be disposed around at least a portion of a perimeter of micro-device 20 in contact with micro-device 20 and the target-substrate surface. Micro-device 20 can comprise a device contact pad 28 disposed on a surface of micro-device 20 opposite the target-substrate surface. A patterned, cured conductive electrode 56 or connection 35 can be connected to device contact pad 28 and to target substrate 20 over at least a portion of dielectric structure 52.

The deposition of liquid curable dielectric 52 material and conductive inks with pattern-printing device 40 to form a structure that extends continuously over an edge of micro-device 20 is facilitated by thin micro-devices 20, for example having a thickness of twenty microns, ten microns, five microns, two microns, or one micron. Liquid materials disposed on an edge of such thin micro-devices 20 can use surface energies and capillary forces to effectively pattern-wise coat edges of micro-devices 20 or edges of dielectric structure 52 and, when cured, can form continuous structures without gaps, e.g., dielectric structure 52 or electrodes 56 or connections 35.

Thus, an interconnected system 90 can comprise a target substrate 10 having a target-substrate surface, a first device 20A disposed on the target-substrate surface, and a second device 20B disposed on the target-substrate surface. First device 20A can comprise a first device contact pad 28 on a side of first device 20A opposite the target-substrate surface and second device 20B can comprise a second device contact pad 28 on a side of second device 20B opposite the target-substrate surface. A patterned first connection 35 (or first electrode 56) can connect first device contact pad 28 to target substrate 10 with a patterned metal layer, for example deposited by evaporation or sputtering and photolithographically patterned. A patterned second connection 35 (or second electrode 56) can connect second device contact pad 28 to target substrate 10 with a patterned metal layer, for example comprising a cured, sintered, annealed, or agglomerated conductive material. For example, patterned second connection 35 (or second electrode 56) can comprise a conductive material distributed in the cured material, for example annealed, agglomerated, or sintered metal (e.g., silver) particles.

Target substrate 10 or module substrate 11 (collectively a substrate) can be a printed circuit board, a substrate of a display, or a semiconductor, glass, metal, ceramic, resin, or polymer substrate. In various embodiments, devices 20 are bare die, integrated circuits, or unpackaged integrated circuits and can be or comprise electronic circuits, optical circuits, light-emitting diodes, or micro-light-emitting diodes. Devices 20 can be chiplets that are micro-transfer printed onto target substrate 10 or larger modules (e.g., having a module substrate 11) that are disposed on target substrate 10. Electrically conductive connections 35 can be wires, conductive traces, cured conductive ink, or other electrical conductors suitable for pattern-wise conducting electricity on a substrate and can be made of copper, silver, gold, aluminum, titanium, tantalum, conductive metal, transparent conductive oxides (TCOs) such as indium tin oxide, or any other patterned conductive material. The wires can be patterned and interconnected or electrically isolated over the substrate using photolithographic or printed circuit board techniques. Optically transmissive connections 35 can be waveguides or optical fibers defined in or on target or modules substrate 10, 11 using high-index optical materials, for example silicon nitride and photolithography or patterned deposition.

Devices 20 can be constructed using foundry fabrication processes used in the art. Layers of materials can be used, including materials such as metals, oxides, nitrides and other materials used in the integrated-circuit art. Each device 20 can be a complete semiconductor integrated circuit. Devices 20 can have different sizes, for example, 1000square microns or 10,000 square microns, 100,000 square microns, or 1 square mm, or larger, can have variable aspect ratios, for example 1:1, 2:1, 5:1, or 10:1, and can be rectangular or can have other shapes. Devices 20 can be small integrated circuits, for example micro-devices 20 (e.g., chiplets), having a thin substrate with a thickness of only a few microns, for example less than or equal to 25 microns, less than or equal to 15 microns, or less than or equal to 10 microns, and having a width or length of 5-10 microns, 10-50 microns, or 50-100 microns. Such devices 20 can be made in a source semiconductor wafer (e.g., a silicon, GaN, or GaAs wafer) having a process side and a back side used to handle and transport the wafer. Devices 20 can be formed using lithographic processes in an active layer on or in the process side of the source wafer. An empty release layer space is formed beneath devices 20 with tethers 24 connecting devices 20 to the source wafer in such a way that pressure applied against devices 20 breaks tethers 24 to release devices 20 from the source wafer, for example with a micro-transfer printing stamp 14. Methods of forming such structures are described, for example, in U.S. Pat. No. 8,889,485 whose contents are incorporated by reference herein in their entirety. Lithographic processes for forming devices 20 in a source wafer, for example transistors, wires, and capacitors, can be found in the integrated circuit art.

According to various embodiments of the present disclosure, the native source wafer can be provided with the devices 20, release layer, tethers 24, and connection posts 54 already formed, or they can be constructed as part of the process of the present disclosure.

Connection posts 54 can be electrical connections formed on a side of a device 20 or on a substrate (e.g., target or module substrate 10, 11) that extend generally perpendicular to the surface of the side. Such connection posts 54 can be formed from metals such as aluminum, titanium, tungsten, copper, silver, gold, or other conductive metals. Connection posts 54 can be formed by repeated masking and deposition processes that build up three-dimensional structures or by etching one or more layers of metal evaporated or sputtered on the side. Such structures can also be made by forming a layer above the device 20 or substrate surface, etching a feature into the surface, filling the feature with a conductive material such as metal, and then removing the layer. In some embodiments, connection posts 54 are made of one or more high elastic modulus metals, such as tungsten. As used herein, a high elastic modulus is an elastic modulus sufficient to maintain the function and structure of connection post 54 when pressed into a target or module substrate 10, 11 (e.g., first and second target contact pads 31, 32) or into device contact pads 28. Connection posts 54 can have a variety of aspect ratios and typically have a peak area smaller than a base area. Connection posts 54 can have a sharp point for embedding in or piercing connections 35, device contact pads 28, or first or second target contact pads 31, 32. Devices 20 with protruding connection posts 54 generally are discussed in U.S. Pat. No. 8,889,485. Chiplets with connection posts 54 are described in U.S. Pat. No. 10,224,460 entitled Micro-Assembled LED Displays and Lighting Elements by Bower et al and in U.S. Pat. No. 10,468,363 entitled Chiplets with Connection Posts by Prevatte et al, whose contents are incorporated herein by reference in their entirety.

If an optional adhesive 12 is provided on the substrate (e.g., target substrate 10 or module substrate 11), each connection post 54 can be driven through adhesive 12 to form an electrical connection with a connection beneath adhesive 12. Adhesive 12 can be cured to more firmly adhere devices 20 to the substrate and maintain a robust electrical connection between connection posts 54 and connections 35 in the presence of mechanical stress. Adhesive 12 can undergo some shrinkage during the curing process that can further strengthen the electrical connectivity and adhesion between connection post 54 and connections 35.

Embodiments of the present disclosure provide advantages over other printing methods described in the prior art. By employing connection posts 54 in devices 20 and a printing method that provides devices 20 on a target substrate 10, a low-cost method for printing devices 20 in large quantities over a target substrate 10 is provided. Furthermore, additional process steps for electrically connecting devices 20 to target substrate 10 are obviated.

In some embodiments, devices 20 are small integrated circuits formed in a semiconductor wafer, for example gallium arsenide or silicon, which can have a crystalline structure. Processing technologies for these materials typically employ high heat and reactive chemicals. However, by employing transfer technologies that do not stress devices 20 or substrate materials, more benign environmental conditions can be used compared to thin-film manufacturing processes. Thus, the present disclosure has an advantage in that flexible substrates such as polymeric substrates, that are intolerant of extreme processing conditions (e.g., heat, chemical, or mechanical processes), can be employed for the substrate. Furthermore, it has been demonstrated that crystalline silicon substrates have strong mechanical properties and, in small sizes, can be relatively flexible and tolerant of mechanical stress. This is particularly true for substrates having 5-micron, 10-micron, 20-micron, 50-micron, or even 100-micron thicknesses.

As is understood by those skilled in the art, the terms “over” and “under” are relative terms and can be interchanged in reference to different orientations of the layers, elements, and substrates included in the present disclosure. For example, a first layer on a second layer, in some implementations means a first layer directly on and in contact with a second layer. In other implementations a first layer on a second layer includes a first layer and a second layer with another layer therebetween.

Having described certain implementations of embodiments, it will now become apparent to one of skill in the art that other implementations incorporating the concepts of the disclosure may be used. Therefore, the disclosure should not be limited to certain implementations but rather should be limited only by the spirit and scope of the following claims.

Throughout the description, where apparatus and systems are described as having, including, or comprising specific components, or where processes and methods are described as having, including, or comprising specific steps, it is contemplated that, additionally, there are apparatus, and systems of the disclosed technology that consist essentially of, or consist of, the recited components, and that there are processes and methods according to the disclosed technology that consist essentially of, or consist of, the recited processing steps.

It should be understood that the order of steps or order for performing certain action is immaterial so long as the disclosed technology remains operable. Moreover, two or more steps or actions in some circumstances can be conducted simultaneously. The invention has been described in detail with particular reference to certain embodiments thereof, but it will be understood that variations and modifications can be effected within the spirit and scope of the invention.

### PARTS LIST

A cross-section line
C center
D1 first distance
D2 second distance
D3 third distance
D4 fourth distance
H horizontal plane/horizontal surface/horizontal direction
V vertical direction
10 target substrate
11 module substrate
12 adhesive/adhesive layer
13 rigid support
14 stamp/stamp post
15 hardened stamp/hardened stamp post/removal stamp/pin
15R pin heating element
16 transfer printer
17 wall/shield
18 removal tool
19 vacuum port
20 device/micro-device
20A first device/faulty device
20B second device/repair device
24 tether
26 circuit
28 device contact pad
30 device location
31 first contact location/first target contact pad
32 second contact location/second target contact pad
33 third contact location/third target contact pad
34 fourth contact location/fourth target contact pad
35 connection/connector
35A first connection
35B second connection
36 cut
40 pattern-printing device
52 dielectric/dielectric structure
54 connection post
55 bond wire
56 electrode
58 connection portion
90 interconnected system
100 provide target substrate step
110 dispose device at device location step
120 connect device to first contact step
122 field coat target substrate step
124 pattern electrode(s) step
130 test device step
140 test passed step
150 operate device step
160 remove device step
170 optional cut connection step
180 optional clean device location step
190 dispose repair device step
200 connect repair device to second contact location step
210 dispose first adhesive at device location step
212 cure first adhesive at first temperature step
214 optional dispose second adhesive at device location step
216 optional cure second adhesive at second temperature step
220 soft cure adhesive step
222 patterned deposition of conductor step
224 cure patterned conductor to form electrode(s) step
230 hard cure adhesive step
300 pattern dielectric liquid step
310 cure dielectric liquid step

1. A method of constructing an interconnected system, comprising:
providing a target substrate having a device location, a first contact location in, on, or adjacent to the device location, and a second contact location in, on, or adjacent to the device location, wherein the first contact location is spatially separate from the second contact location;
disposing a first device onto the target substrate at the device location;
connecting the first device to the first contact location;
removing the first device;
disposing a second device onto the target substrate at least partly in the device location; and
connecting the second device to the second contact location.

2. The method of claim 1, further comprising testing the first device to determine if the first device is faulty.

3. The method of claim 1, wherein the first contact location is connected to the second contact location.

4. The method of claim 1, wherein connecting the first device to the first contact location comprises connecting the first device to the first contact location with at least one of: a thin-film interconnect; a connection post; a pattern-printed conductive or transmissive connector or wire; and wire bonding; and

5. The method of claim 1, wherein connecting the second device to the second contact location comprises connecting the second device to the second contact location with at least one of: a thin-film connection; a pattern-printed conductive or transmissive connector or wire; a connection post; and wire bonding.

6. The method of claim 1, wherein the first device has a first size and a first aspect ratio, the second device has a second size and a second aspect ratio, and wherein the first size is substantially the same as the second size or the first aspect ratio is substantially the same as the second aspect ratio, or both.

7. The method of claim 1, further comprising one or both of:
micro-transfer printing the first device onto the target substrate at the device location; and
micro-transfer printing the second device onto the target substrate at the device location.

8. The method of claim 1, wherein one or both of the first device and the second device comprises a connection post, wherein the method further comprises one of both of connecting the first device to the first contact location by pressing the connection post to the first contact location by micro-transfer printing, and connecting the second device to the second contact location by pressing the connection post to the second contact location by micro-transfer printing.

9. The method of claim 1, wherein the target substrate comprises a third contact location in, on, or adjacent to the device location, wherein the third contact location is spatially separate from the first contact location and from the second contact location, and wherein the third contact location is connected to the first contact location and to the second contact location;
wherein the method further comprises:
removing the second device;
disposing a third device at least partially in the device location; and
connecting the third device to the third contact location.

10. The method of claim 1, further comprising disposing the first device on the target substrate with a first orientation and disposing the second device on the target substrate with a second orientation that is substantially the same as the first orientation.

11. The method of claim 1, further comprising disposing the first device on the target substrate with a first orientation and disposing the second device on the target substrate with a second orientation, wherein the first orientation is rotated with respect to the second orientation, or the second orientation is horizontally offset on the target substrate with respect to the first orientation, or both.

12. The method of claim 1, further comprising removing the first device.

13. The method of claim 1, further comprising disposing a first adhesive on the target substrate before disposing the first device.

14. The method of claim 13, further comprising at least partially curing the first adhesive.

15. The method of claim 14, wherein the first adhesive is cured at a first curing temperature, the method further comprising annealing the target substrate at an anneal temperature that is less than the first curing temperature.

16. The method of claim 14, wherein disposing the second device onto the target substrate does not include disposing a second adhesive on the target substrate.

17. The method of claim 14, further comprising testing the first device after at least partially curing the first adhesive.

18. The method of claim 13, further comprising removing the first device after disposing the first device and removing at least a portion of the first adhesive.

19. The method of claim 13, further comprising disposing a second adhesive on the target substrate before disposing the second.

20. The method of claim 19, further comprising at least partially curing the second adhesive.

21. The method of claim 20, further comprising testing the second device after at least partially curing the second adhesive 22. The method of claim 1, wherein one or both of the first contact location and the second contact location comprises a target contact pad.

23. The method of claim 1, wherein connecting the first device to the first contact location comprises at least one of: forming an electrical connection between the first device and the first contact location, and forming an optical connection between the first device and the first contact location.

24. The method of claim 1, wherein connecting the second device to the second contact location comprises at least one of: forming an electrical connection between the second device and the second contact location, and forming an optical connection between the second device and the second contact location.

25. An interconnected system, comprising:
a target substrate having a device location, a first contact location in, on, or adjacent to the device location, and a second contact location in, on, or adjacent to the device location, wherein the first contact location is spatially separate from the second contact location;
a second device disposed at least partially in the device location;
a damaged or disconnected first connection to the first contact location; and
a second connection connecting the second contact location to the second device.

26. The interconnected system of claim 25, wherein the first contact location is connected to the second contact location.

27. The interconnected system of claim 25, wherein the damage or disconnected connection comprises at least one of:
(i) a portion of a thin-film connection in or connected to the first contact location,
(ii) an indentation, divot, or hole in a contact pad or connector in or connected to the first contact location,
(iii) a portion of a pattern-printed conductive wire in or connected to the first contact location,
(iv) a portion of a photolithographically defined wire in or connected to the first contact location, and
(v) a portion of a wire bond.

28. The interconnected system of claim 25, wherein the first contact location is disposed with a same rotation or horizontal offset as the second contact location with respect to the device location.

29. The interconnected system of claim 25, wherein the device location has a location area with a center, the first contact location is disposed a first distance from the center of the device location, and the second contact location is disposed a second distance from the center of the device location.

30. The interconnected system of claim 29, wherein the first distance is substantially equal to the second distance.

31. The interconnected system of claim 25, wherein one or both of the first device and the second device are adhered to the target substrate.

32. The interconnected system of claim 31, wherein the first device or the second device are adhered to the target substrate with an adhesive or van der Waals forces, or both.

33. The interconnected system of claim 25, wherein the second device is a micro-transfer-printed device comprising a broken or separated tether.

34. The interconnected system of claim 25, wherein the second device comprises or is disposed upon a module having a module substrate separate from the target substrate.

35. The interconnected system of claim 25, wherein the second device is a bare unpackaged integrated circuit.

36. The interconnected system of claim 25, wherein the second device comprises a device contact pad having a device contact area that is sized to connect to a first electrode connected to the first contact location and to a second electrode connected to the second contact location.

37. The interconnected system of claim 25, wherein the second device comprises a device contact pad and the second connection is connected to the device contact pad and extends at least partly over the first connection.

38. The interconnected system of claim 25, wherein one or both of the first contact location and the second contact location comprises a target contact pad.

39. The interconnected system of claim 25, wherein the second contact location is spatially rotated with respect to the first contact location.

40. The interconnected system of claim 25, wherein the first contact location and the second contact location are symmetrically disposed about a center of the device location or a center of the second device so that the first contact location and the second contact location are disposed in a line through and equidistant from on opposite sides of the center.

41. A method of repairing a micro-transfer-printed system, the method comprising
providing a target substrate having a target-substrate surface and a first contact location;
disposing a first device onto the target-substrate surface, the first device comprising a first device contact pad;
connecting the first device to the target substrate by patterning a metal layer to form a patterned first connection from the first device contact pad to the target-substrate surface;
disposing a second device onto the target-substrate surface, the second device comprising a second device contact pad; and
connecting the second device by forming a patterned second connection from the second device contact pad to the target-substrate surface.

42. The method of claim 41, wherein connecting the first device to the target substrate comprises evaporating or sputtering metal onto the target substrate to form the metal layer.

43. The method of claim 41, wherein connecting the second device comprises pattern-wise dispensing a liquid and curing the liquid to form the patterned second connection.

44. The method of claim 41, wherein the patterned second connection comprises one or more of metallic nanoparticles, a conductive polymer, or polythiophene.
